(19) United States
(12) Patent Application Publication
(10) Pub. No.: US 2026/0194614 A1
(43) Pub. Date: Jul. 9, 2026

(54) MAGNETIC FIELD SENSING DEVICE

(71) Applicants: Shanghai Naxi Microelectronics Co., Ltd., Shanghai (CN); SUZHOU NOVOSENSE MICROELECTRONICS CO., LTD., Suzhou (CN)

(72) Inventors: Fute YUAN, Suzhou (CN); Xuanzhong JIANG, Suzhou (CN); Long ZHANG, Suzhou (CN)

(73) Assignees: Shanghai Naxi Microelectronics Co., Ltd., Shanghai (CN); SUZHOU NOVOSENSE MICROELECTRONICS CO., LTD., Suzhou (CN)

(21) Appl. No.: 19/229,996

(22) Filed: Jun. 5, 2025

(30) Foreign Application Priority Data
Jan. 3, 2025 (CN) 202510015655.4

(51) Int. Cl. G01R 35/00; G01R 33/07; G01R 33/09

(52) U.S. Cl. CPC G01R 35/005; G01R 33/07; G01R 33/09

(57) ABSTRACT

The present application discloses a magnetic field sensing device, comprising: a first magnetic field generating unit, configured to apply a predetermined first excitation magnetic field to a first sensing unit; a first sensing unit, arranged in a first region and configured to sense an ambient magnetic field to generate a first sensing signal; a second sensing unit, arranged in the first region and configured to sense an ambient magnetic field to generate a second sensing signal; and an operation unit, configured to generate a calibration signal based on the first sensing signal and the second sensing signal, wherein the calibration signal includes information corresponding to the first excitation magnetic field, and the calibration signal is configured to calibrate the first sensing signal and/or the second sensing signal. The magnetic field sensing device provided by the present application exhibits high sensitivity and is capable of achieving targeted linear error calibration.

### TECHNICAL FIELD

The present application relates to a technical field of test and measurement, and in particular, to a magnetic field sensing device.

### BACKGROUND

Magnetic field sensing devices are used to detect magnetic fields and have diverse application scenarios. In consumer electronics, examples include triaxial magnetometers for measuring geomagnetic fields, magnetic displacement meters for measuring lens displacement, and magnetic switches for detecting screen open/close status. In industrial and transportation applications, they encompass angle sensors, current sensors, etc.

To ensure measurement stability, magnetic field sensing devices can be fabricated using magnetoresistance. However, such magnetic field sensing device rely on properties of magnetic materials, resulting in a physical characteristic where the linearity error of the output curve increases with the intensity of the measured magnetic field. A calibration device can be employed to address this calibration requirement.

Two sets of sensing units are used to measure the target magnetic field in the prior arts, achieving linearity error cancellation through mutual offset. However, the offset mechanism inherently reduces the sensitivity of the magnetic field sensing device, rendering the magnetic field sensing device unsuitable for applications requiring high sensitivity.

### SUMMARY

One of the objectives of the present application is to provide a magnetic field sensing device to solve the technical problems of low sensitivity and poor output accuracy in existing magnetic field sensing devices in the prior art.

To achieve one of the above objectives of the present application, an embodiment of the present application provides a magnetic field sensing device, comprising: a first magnetic field generating unit, configured to apply a predetermined first excitation magnetic field to a first sensing unit; a first sensing unit, arranged in a first region, configured to sense an ambient magnetic field to generate a first sensing signal; a second sensing unit, arranged in the first region, configured to sense an ambient magnetic field to generate a second sensing signal; and an operation unit, configured to generate a calibration signal based on the first sensing signal and the second sensing signal, wherein the calibration signal includes information corresponding to the first excitation magnetic field, and the calibration signal is configured to calibrate the first sensing signal and/or the second sensing signal.

Compared with the prior art, the magnetic field sensing device provided by the present application employs two sensing units located in a same region, with one of them being subjected to a predetermined excitation magnetic field. By performing operations on signals generated by the two sensing units, a calibration signal representing the excitation magnetic field information is extracted. Since the information of the excitation magnetic field is predetermined, if the excitation magnetic field information contained in the calibration signal differs from the predetermined excitation magnetic field information, it can be determined that the magnetic field sensing device has an error, and the sensing signals can be calibrated based on the difference. In this process, as the two sensing units are located in a same region, it facilitates the formation of a calibration signal related to linear errors between the two sensing signals, thereby enabling targeted and rapid calibration. Since both sensing units are configured to be sensitive to the ambient magnetic field, the overall device exhibits high sensitivity.

### BRIEF DESCRIPTION OF THE DRAWINGS

FIG. 1 is a schematic structural diagram of a magnetic field sensing device in an embodiment of the present application.

FIG. 2 is a schematic structural diagram of the magnetic field sensing device in a first embodiment of the present application.

FIG. 3 is a schematic structural diagram of the magnetic field sensing device in a second embodiment of the present application.

FIG. 4 is a schematic structural diagram of the magnetic field sensing device in a third embodiment of the present application.

FIG. 5 is a schematic structural diagram of the magnetic field sensing device in a first example of the present application.

FIG. 6 is a schematic structural diagram of the magnetic field sensing device in a second example of the present application.

FIG. 7 is a schematic structural diagram of the magnetic field sensing device in a third example of the present application.

FIG. 8 is a schematic structural diagram of the magnetic field sensing device in a fourth example of the present application.

FIG. 9 is a schematic structural diagram of the magnetic field sensing device in a fifth example of the present application.

FIG. 10 is a schematic structural diagram of the magnetic field sensing device in a sixth example of the present application.

FIG. 11 is a schematic structural diagram of the magnetic field sensing device in a seventh example of the present application.

FIG. 12 is a schematic structural diagram of the magnetic field sensing device in an eighth example of the present application.

FIG. 13 is a schematic structural diagram of the magnetic field sensing device in a ninth example of the present application.

FIG. 14 is a schematic structural diagram of the magnetic field sensing device in a tenth example of the present application.

FIG. 15 is a schematic structural diagram of the magnetic field sensing device in an eleventh example of the present application.

FIG. 16 is a schematic structural diagram of the magnetic field sensing device in a twelfth example of the present application.

FIG. 17 is a schematic structural diagram of the magnetic field sensing device in a thirteenth example of the present application.

FIG. 18 is a schematic structural diagram of the magnetic field sensing device in a fourteenth example of the present application.

FIG. 19 is a schematic structural diagram of the magnetic field sensing device in a fifteenth example of the present application.

FIG. 20 is a schematic structural diagram of the magnetic field sensing device in a sixteenth example of the present application.

FIG. 21 is a schematic structural diagram of the magnetic field sensing device in a seventeenth example of the present application.

FIG. 22 is a schematic structural diagram of the magnetic field sensing device in an eighteenth example of the present application.

FIG. 23 is a schematic structural diagram of the magnetic field sensing device in a nineteenth example of the present application.

FIG. 24 is a schematic structural diagram of a sensing unit in an embodiment of the present application.

FIG. 25 is a partial schematic structural diagram of a sensing unit in another embodiment of the present application.

FIG. 26 is a schematic structural diagram of a sensing unit in another embodiment of the present application.

### DETAILED DESCRIPTION

The following detailed description of the present application will be made with reference to the accompanying drawings showing specific embodiments. However, these embodiments do not limit the present application, and any structural, methodological, or functional modifications made by those skilled in the art based on these embodiments fall within the protection scope of the present application.

It should be noted that the term “comprise” or any of its other variants is intended to cover a non-exclusive inclusion, such that a process, method, article, or device that comprises a series of elements includes not only those elements but also other elements not explicitly listed, or elements inherent to such process, method, article, or device.

Furthermore, the terms “first”, “second”, “third” and so on are used merely for descriptive purposes and should not be understood as indicating or implying relative importance. There is no necessary correlation between the terms “first”, “second”, “third” and so on; for example, an embodiment of the present application that includes a “second” does not necessarily mean that the embodiment or the example must include a “first”, and so on.

An embodiment of the present application provides a magnetic field sensing device, as shown in FIG. 1.

The magnetic field sensing device is used for sensing magnetic field information. Specifically, the magnetic field sensing device can be used for sensing information of a signal magnetic field in an ambient magnetic field, to achieve functions such as motion data and position data measurement.

The magnetic field sensing device comprises a first sensing unit 10.

The first sensing unit 10 is configured to sense magnetic fields. The first sensing unit 10 is configured to sense an ambient magnetic field in the environment of the first sensing unit 10, wherein the ambient magnetic field includes a signal magnetic field; the ambient magnetic field may also include other magnetic fields, such as an excitation magnetic field described later.

In an embodiment, the first sensing unit 10 comprises a magnetoresistor; specifically, the first sensing unit 10 may be constituted by a magnetoresistor.

In an embodiment, the first sensing unit 10 comprises a Hall unit; specifically, the first sensing unit 10 may be constituted by a Hall unit.

The magnetic field sensing device comprises a first magnetic field generating unit 11.

The first magnetic field generating unit 11 is configured to apply a predetermined first excitation magnetic field Br1 to the first sensing unit 10.

The term “predetermined” indicates that the direction and magnetic field intensity of the first excitation magnetic field Br1 are predetermined and known.

The first magnetic field generating unit 11 may be configured as structures such as a coil, magnet, or other structures capable of generating local magnetic fields to apply the first excitation magnetic field Br1.

The first magnetic field generating unit 11 may be arranged close to the first sensing unit 10 to apply the first excitation magnetic field Br1 to the first sensing unit 10.

The first excitation magnetic field Br1 applied by the first magnetic field generating unit 11 has at least a magnetic field component along the sensing direction of the first sensing unit 10.

In an embodiment, the first sensing unit 10 may have a sensing direction parallel to a plane where the first sensing unit 10 is located. For example, the first sensing unit 10 may have a sensing direction along a first direction X or its opposite direction; alternatively, the first sensing unit 10 may have a sensing direction along a second direction Y or its opposite direction.

Correspondingly, the first magnetic field generating unit 11 may apply the first excitation magnetic field Br1 parallel to the plane where the first sensing unit 10 is located. For example, when the first sensing unit 10 has a sensing direction along the first direction X, the first excitation magnetic field Br1 is along the first direction X or its opposite direction; alternatively, when the first sensing unit 10 has a sensing direction along the second direction Y, the first excitation magnetic field Br1 is along the second direction Y or its opposite direction.

In an embodiment, the first sensing unit 10 may have a sensing direction perpendicular to the plane where the first sensing unit 10 is located. For example, the first sensing unit 10 may have a sensing direction along a third direction Z or its opposite direction.

Correspondingly, the first magnetic field generating unit 11 may apply the first excitation magnetic field Br1 perpendicular to the plane where the first sensing unit 10 is located. For example, when the first sensing unit 10 has a sensing direction along the third direction Z, the first excitation magnetic field Br1 is along the third direction Z or its opposite direction.

The first sensing unit 10 is arranged in a first region S1.

The first sensing unit 10 is configured to sense an ambient magnetic field to generate a first sensing signal.

The ambient magnetic field sensed by the first sensing unit 10 includes the first excitation magnetic field Br1.

The ambient magnetic field sensed by the first sensing unit 10 includes either the overall ambient magnetic field of the environment where the magnetic field sensing device is located, or the magnetic field component of the overall ambient magnetic field at the first region S1.

The first sensing signal may be in digital or analog form. The digital form sensing signal may be data such as magnetic field intensity, magnetic field direction, etc. ; the analog form sensing signal may be current signal or voltage signal.

The magnetic field sensing device comprises a second sensing unit 20.

The second sensing unit 20 is arranged in the first region S1. The second sensing unit 20 may be arranged at a same location as the first sensing unit 10, or may be arranged at a position close to the first sensing unit 10 within the first region S1.

The second sensing unit 20 is configured to sense an ambient magnetic field to generate a second sensing signal.

The ambient magnetic field sensed by the second sensing unit 20 includes either the overall ambient magnetic field of the environment where the magnetic field sensing device is located, or the magnetic field component of the overall ambient magnetic field at the first region S1.

The second sensing signal may be in digital or analog form.

The difference between the second sensing signal and the first sensing signal is used to characterize the first excitation magnetic field Br1. Preferably, the only difference in the ambient magnetic field between the first sensing unit 10 and the second sensing unit 20 is the first excitation magnetic field Br1.

The magnetic field sensing device comprises an operation unit 800.

The operation unit 800 is configured to generate a calibration signal based on the first sensing signal and the second sensing signal. The calibration signal includes information corresponding to the first excitation magnetic field Br1.

In an embodiment, the calibration signal is configured to calibrate the first sensing signal.

In an embodiment, the calibration signal is configured to calibrate the second sensing signal.

In an embodiment, the calibration signal is configured to calibrate both the first sensing signal and the second sensing signal.

Thus, by disposing two sensing units in the same first region S1, with one of them being applied with a predetermined first excitation magnetic field Br1, the information corresponding to the excitation magnetic field can be determined using the sensing signals output by both units. If there is a difference between the information corresponding to the excitation magnetic field in the calibration signal and the predetermined information of the first excitation magnetic field Br1, it indicates that the magnetic field sensing device has linear errors caused by temperature, humidity, or stress, etc. Therefore, the sensing signals can be calibrated based on the calibration signal to overcome such errors caused by the magnetic field sensing device's own structure. Moreover, since both sensing units sense the ambient magnetic field rather than specific excitation magnetic field or signal magnetic field, the signal sensing of the sensing units does not suffer loss due to cancellation or other means, thereby achieving stronger sensing sensitivity.

The operation unit 800 is configured to calibrate the sensing signal based on a difference between a value of the calibration signal and a first predetermined value. The sensing signal includes the first sensing signal and/or the second sensing signal.

The first predetermined value is determined according to the information of the first excitation magnetic field; in an embodiment, the first predetermined value is determined according to a magnetic field intensity of the first excitation magnetic field Br1. For example, the first predetermined value equals the magnetic field intensity of the first excitation magnetic field Br1.

In an embodiment, when a detected value corresponding to the magnetic field intensity of the first excitation magnetic field in the calibration signal is not equal to the first predetermined value, it indicates that the sensing condition of the magnetic field sensing device does not match the actual condition, and the sensing signal is calibrated at this time.

For example, when the detected value is smaller than the first predetermined value, it indicates that the sensing condition of the magnetic field sensing device is too low, and the sensing signal is calibrated and increased at this time.

For example, when the detected value is greater than the first predetermined value, it indicates that the sensing condition of the magnetic field sensing device is too high, and the sensing signal is calibrated and decreased at this time.

In an embodiment, the magnetic field sensing device further comprises a first amplifier 71. The first amplifier 71 is configured to amplify an input signal by a first amplification factor A1 and output an amplified signal. An input terminal of the first amplifier 71 is coupled to the first sensing unit 10, and an output terminal of the first amplifier 71 is coupled to the operation unit 800.

In an embodiment, the magnetic field sensing device further comprises a second amplifier 72. The second amplifier 72 is configured to amplify an input signal by a second amplification factor A2 and output an amplified signal. An input terminal of the second amplifier 72 is coupled to the second sensing unit 20, and an output terminal of the second amplifier 72 is coupled to the operation unit 800.

In an embodiment, the first sensing unit 10 and the second sensing unit 20 are configured to output sensing signals in voltage form. In the embodiment, the operation unit 800 receives a first sensing signal V1 and a second sensing signal V2.

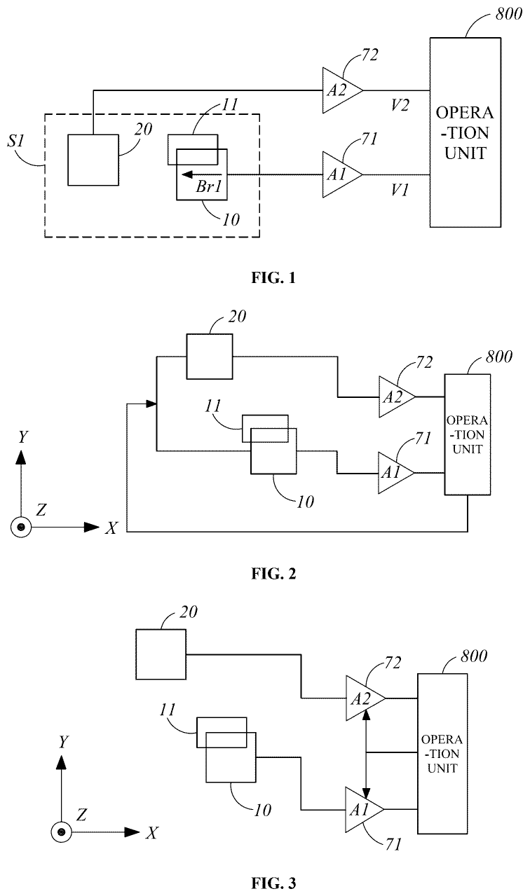

FIG. 2 shows a first embodiment of the present application. The differences between the first embodiment and the technical solution shown in FIG. 1 will be explained below, while similar aspects will not be repeated; in other words, the embodiments shown in FIGS. 1 and 2 can be combined or separated.

In an example, an output terminal of the operation unit 800 is coupled to the first sensing unit 10.

In an example, an output terminal of the operation unit 800 is coupled to the second sensing unit 20.

In an example, the operation unit 800 is configured to adjust a driving current. For example, an output terminal of the operation unit 800 is coupled to the first sensing unit 10 to adjust the driving current of the first sensing unit 10. For example, an output terminal of the operation unit 800 is coupled to the second sensing unit 20 to adjust the driving current of the second sensing unit 20.

Specifically, the operation unit 800 may adjust the driving current based on a difference between the value of the calibration signal and the first predetermined value. When the value of the calibration signal is smaller than the first predetermined value, the operation unit 800 adjusts to increase the driving current; conversely, the operation unit 800 adjusts to decrease the driving current.

In an example, the operation unit 800 is configured to adjust a driving voltage. For example, an output terminal of the operation unit 800 is coupled to the first sensing unit 10 to adjust the driving voltage of the first sensing unit 10. For example, an output terminal of the operation unit 800 is coupled to the second sensing unit 20 to adjust the driving voltage of the second sensing unit 20.

Specifically, the operation unit 800 may adjust the driving voltage based on a difference between the value of the calibration signal and the first predetermined value. When the value of the calibration signal is smaller than the first predetermined value, the operation unit 800 adjusts to increase the driving voltage; conversely, the operation unit 800 adjusts to decrease the driving voltage.

FIG. 3 shows a second embodiment of the present application. The differences between the second embodiment and the technical solution shown in FIG. 1 will be explained below, while similar aspects will not be repeated.

In an example, the magnetic field sensing device comprises a first amplifier 71. An input terminal of the first amplifier 71 is coupled to an output terminal of the first sensing unit 10, and an output terminal of the first amplifier 71 is coupled to a first input terminal of the operation unit 800. An output terminal of the operation unit 800 is coupled to the first amplifier 71; for example, an output terminal of the operation unit 800 is coupled to a control terminal of the first amplifier 71 to adjust the amplification factor of the first amplifier 71.

Specifically, the operation unit 800 may adjust an amplification factor of the first amplifier 71 based on a difference between the value of the calibration signal and the first predetermined value. When the value of the calibration signal is smaller than the first predetermined value, the operation unit 800 adjusts to increase the amplification factor of the first amplifier 71; conversely, the operation unit 800 adjusts to decrease the amplification factor of the first amplifier 71.

In an example, the magnetic field sensing device comprises a second amplifier 72. An input terminal of the second amplifier 72 is coupled to an output terminal of the second sensing unit 20, and an output terminal of the second amplifier 72 is coupled to a second input terminal of the operation unit 800. An output terminal of the operation unit 800 is coupled to the second amplifier 72; for example, an output terminal of the operation unit 800 is coupled to a control terminal of the second amplifier 72 to adjust the amplification factor of the second amplifier 72.

Specifically, the operation unit 800 may adjust an amplification factor of the second amplifier 72 based on a difference between the value of the calibration signal and the first predetermined value. When the value of the calibration signal is smaller than the first predetermined value, the operation unit 800 adjusts to increase the amplification factor of the second amplifier 72; conversely, the operation unit 800 adjusts to decrease the amplification factor of the second amplifier 72.

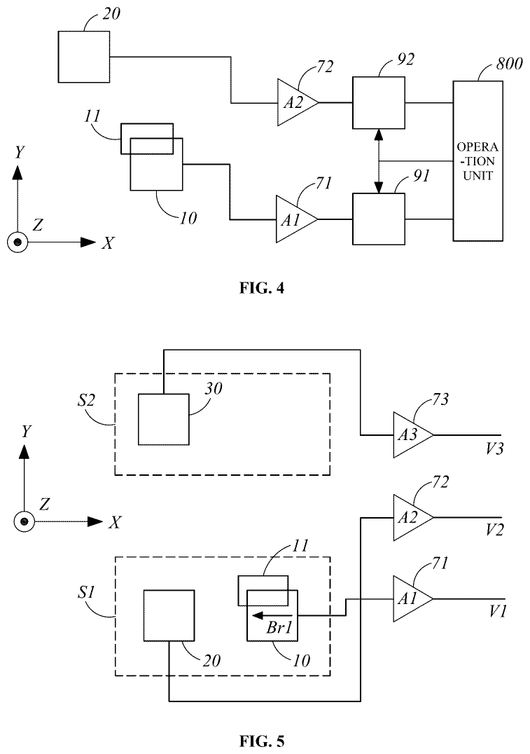

FIG. 4 shows a third embodiment of the present application. The differences between the third embodiment and the technical solution shown in FIG. 1 will be explained below, while similar aspects will not be repeated.

In an example, the operation unit 800 is configured to adjust a computational gain of the first sensing signal based on the calibration signal.

Specifically, the operation unit 800 may adjust a computational gain of the first sensing signal based on a difference between the value of the calibration signal and the first predetermined value. When the value of the calibration signal is smaller than the first predetermined value, the operation unit 800 adjusts to increase the computational gain of the first sensing signal; conversely, the operation unit 800 adjusts to decrease the computational gain of the first sensing signal.

For example, the magnetic field sensing device comprises a first processing unit 91. The first processing unit 91 is configured to process an input signal according to a predetermined computational gain and output a processed signal. An input terminal of the first processing unit 91 is coupled to the first amplifier 71 (or directly coupled to the first sensing unit 10), an output terminal of the first processing unit 91 is coupled to the operation unit 800, and an output terminal of the operation unit 800 is coupled to the first processing unit 91; for example, an output terminal of the first processing unit 91 is coupled to an input terminal of the operation unit 800, and an output terminal of the operation unit 800 is coupled to a control terminal of the first processing unit 91.

Alternatively, for example, the first sensing signal is directly coupled to the operation unit 800, and the operation unit 800 is configured to adjust the computational gain of the first sensing signal based on the calibration signal.

In an example, the operation unit 800 is configured to adjust the computational gain of the second sensing signal based on the calibration signal.

Specifically, the operation unit 800 may adjust a computational gain of the second sensing signal based on a difference between the value of the calibration signal and the first predetermined value. When the value of the calibration signal is smaller than the first predetermined value, the operation unit 800 adjusts to increase the computational gain of the second sensing signal; conversely, the operation unit 800 adjusts to decrease the computational gain of the second sensing signal.

For example, the magnetic field sensing device comprises a second processing unit 92. The second processing unit 92 is configured to process an input signal according to a predetermined computational gain and output a processed signal. An input terminal of the second processing unit 92 is coupled to the second amplifier 72 (or directly coupled to the second sensing unit 20), an output terminal of the second processing unit 92 is coupled to the operation unit 800, and an output terminal of the operation unit 800 is coupled to the second processing unit 92; for example, an output terminal of the second processing unit 92 is coupled to an input terminal of the operation unit 800, and an output terminal of the operation unit 800 is coupled to a control terminal of the second processing unit 92.

Alternatively, for example, the second sensing signal is directly coupled to the operation unit 800, and the operation unit 800 is configured to adjust the computational gain of the second sensing signal based on the calibration signal.

FIG. 5 shows a first example of the present application. The differences between the first example and the technical solution shown in FIG. 1 will be explained below, while similar aspects will not be repeated.

The magnetic field sensing device comprises a third sensing unit 30.

The third sensing unit 30 is arranged in a second region S2. The second region S2 is different from the first region S1. The difference between the two regions means that the first region S1 and the second region S2 at least do not completely overlap; the first region S1 and the second region S2 may partially overlap; or the first region S1 and the second region S2 may not overlap at all.

The third sensing unit 30 is configured to sense an ambient magnetic field to generate a third sensing signal.

The ambient magnetic field sensed by the third sensing unit 30 includes either the overall ambient magnetic field of the environment where the magnetic field sensing device is located, or the magnetic field component of the overall ambient magnetic field at the second region S2.

In combination with FIG. 1, the operation unit 800 is configured to determine a magnetic field sensing signal of the magnetic field sensing device based on a value of the second sensing signal and a value of the third sensing signal.

When the second sensing signal is used to characterize the magnetic field component of the ambient magnetic field at the first region S1, and the third sensing signal is used to characterize the magnetic field component of the ambient magnetic field at the second region S2, the operation unit 800 is configured to achieve common-mode or differential output based on the magnetic field components at two different regions. The common-mode output reflects the overall magnetic field intensity of the ambient magnetic field, while the differential output reflects the distribution gradient of the ambient magnetic field at different regions.

In the first example, the operation unit 800 may determine a common-mode sensing signal corresponding to the ambient magnetic field based on a sum of the value of the second sensing signal and the value of the third sensing signal. The magnetic field sensing signal of the magnetic field sensing device includes the common-mode sensing signal.

In the first example, the operation unit 800 may determine a differential sensing signal corresponding to the ambient magnetic field based on a difference between the value of the second sensing signal and the value of the third sensing signal. The magnetic field sensing signal of the magnetic field sensing device includes the differential sensing signal.

In a specific example, the magnetic field sensing device further comprises a third amplifier 73. The third amplifier 73 is configured to amplify an input signal by a third amplification factor A3 and output an amplified signal. An input terminal of the third amplifier 73 is coupled to the third sensing unit 30, and an output terminal of the third amplifier 73 is coupled to the operation unit 800. An output terminal of the operation unit 800 may also be coupled to a control terminal of the third amplifier 73 to adjust the amplification factor of the third amplifier 73.

In a specific example, the third sensing unit 30 is configured to output a sensing signal in voltage form. In the example, the operation unit 800 receives a third sensing signal V3.

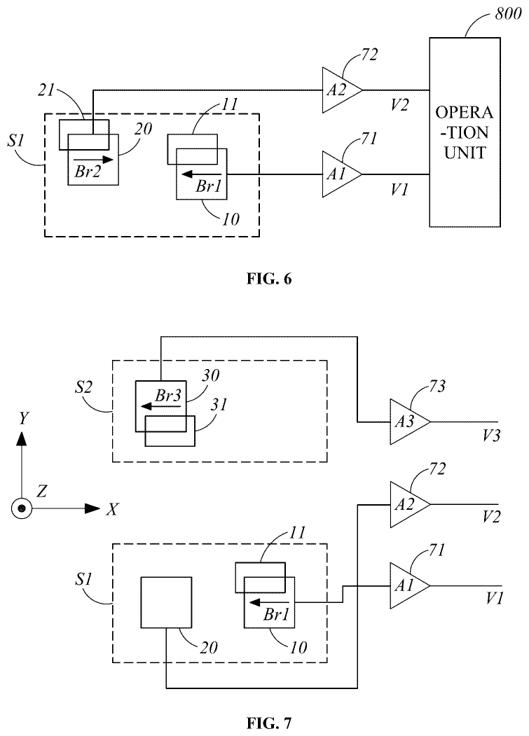

FIG. 6 shows a second example of the present application. The differences between the second example and the technical solution shown in FIG. 1 will be explained below, while similar aspects will not be repeated.

The magnetic field sensing device comprises a second magnetic field generating unit 21.

The second magnetic field generating unit 21 is configured to apply a predetermined second excitation magnetic field Br2 to the second sensing unit 20. The direction and magnetic field intensity of the second excitation magnetic field Br2 are predetermined and known.

The second magnetic field generating unit 21 may be configured as structures such as a coil, magnet, or other structures capable of generating local magnetic fields to apply the second excitation magnetic field Br2.

The second magnetic field generating unit 21 may be arranged close to the second sensing unit 20 to apply the second excitation magnetic field Br2 to the second sensing unit 20.

The second excitation magnetic field Br2 applied by the second magnetic field generating unit 21 has at least a magnetic field component along the sensing direction of the second sensing unit 20. For example, when the second sensing unit 20 has a sensing direction along the first direction X or its opposite direction, the second magnetic field generating unit 21 applies the second excitation magnetic field Br2 in the first direction X to the second sensing unit 20.

Correspondingly, the ambient magnetic field sensed by the second sensing unit 20 includes the second excitation magnetic field Br2.

In a specific example, the ambient magnetic field sensed by the first sensing unit 10 includes the first excitation magnetic field Br1 and a first signal magnetic field corresponding to the first region S1. In a specific example, the ambient magnetic field sensed by the second sensing unit 20 includes the second excitation magnetic field Br2 and the first signal magnetic field.

In a specific example, the first sensing signal includes information corresponding to the first signal magnetic field and information corresponding to the first excitation magnetic field Br1. In a specific example, the second sensing signal includes information corresponding to the first signal magnetic field and information corresponding to the second excitation magnetic field Br2.

Thus, based on the first sensing signal and the second sensing signal, a calibration signal containing information corresponding to the excitation magnetic field can be extracted to calibrate the output of the magnetic field sensing device according to the difference between the value of the calibration signal and the first predetermined value, while the information of the first signal magnetic field can be extracted to form a magnetic field sensing output for the first region S1.

In a specific example, the operation unit 800 is configured to determine the first signal magnetic field based on the first sensing signal and the second sensing signal.

In a specific example, the operation unit 800 is configured to determine the calibration signal based on the first sensing signal and the second sensing signal.

The second excitation magnetic field Br2 has a direction opposite to the first excitation magnetic field Br1. In a specific example, the second excitation magnetic field Br2 has a same magnetic field intensity as the first excitation magnetic field Br1.

In the example, the operation unit 800 is specifically configured to determine the first signal magnetic field based on a sum of the value of the first sensing signal and the value of the second sensing signal. Thus, magnetic field sensing is achieved by removing the excitation magnetic field from the first sensing signal and the second sensing signal through computation to extract the first signal magnetic field.

The operation unit 800 is specifically configured to determine the calibration signal based on a difference between the value of the first sensing signal and the value of the second sensing signal. Thus, calibration of the sensing output is achieved by removing the first signal magnetic field from the first sensing signal and the second sensing signal through computation to extract the calibration signal corresponding to the excitation magnetic field.

FIG. 7 shows a third example of the present application. The differences between the third example and the technical solution shown in FIG. 1 will be explained below, while similar aspects will not be repeated.

The magnetic field sensing device comprises a third magnetic field generating unit 31.

The third magnetic field generating unit 31 is configured to apply a predetermined third excitation magnetic field Br3 to the third sensing unit 30. The direction and magnetic field intensity of the third excitation magnetic field Br3 are predetermined and known.

The third magnetic field generating unit 31 may be configured as structures such as a coil, magnet, or other structures capable of generating local magnetic fields to apply the third excitation magnetic field Br3.

The third magnetic field generating unit 31 may be arranged close to the third sensing unit 30 to apply the third excitation magnetic field Br3 to the third sensing unit 30.

The third excitation magnetic field Br3 applied by the third magnetic field generating unit 31 has at least a magnetic field component along the sensing direction of the third sensing unit 30. For example, when the third sensing unit 30 has a sensing direction along the first direction X or its opposite direction, the third magnetic field generating unit 31 applies the third excitation magnetic field Br3 in the opposite direction of the first direction X to the third sensing unit 30.

The magnetic field sensing device comprises a third sensing unit 30.

The third sensing unit 30 may be configured as shown in the first example in FIG. 5.

The third sensing unit 30 is arranged in the second region S2. The second region S2 is different from the first region S1.

The third sensing unit 30 is configured to sense an ambient magnetic field to generate a third sensing signal.

The ambient magnetic field sensed by the third sensing unit 30 includes either the overall ambient magnetic field of the environment where the magnetic field sensing device is located, or the magnetic field component of the overall ambient magnetic field at the second region S2.

Correspondingly, the ambient magnetic field sensed by the third sensing unit 30 includes the third excitation magnetic field Br3.

In a specific example, the ambient magnetic field sensed by the first sensing unit 10 includes the first excitation magnetic field Br1 and a first signal magnetic field corresponding to the first region S1. In a specific example, the ambient magnetic field sensed by the third sensing unit 30 includes the third excitation magnetic field Br3 and a second signal magnetic field corresponding to the second region S2.

In a specific example, the first sensing signal includes information corresponding to the first signal magnetic field and information corresponding to the first excitation magnetic field Br1. In a specific example, the third sensing signal includes information corresponding to the second signal magnetic field and information corresponding to the third excitation magnetic field Br3.

Thus, based on the first sensing signal and the third sensing signal, a difference or superposition result of the first signal magnetic field and the second signal magnetic field can be extracted to form a magnetic field sensing output for the first region S1 and the second region S2.

In a specific example, the operation unit 800 is configured to determine a magnetic field sensing signal of the magnetic field sensing device based on the first sensing signal and the third sensing signal.

The third excitation magnetic field Br3 has a same direction as the first excitation magnetic field Br1. In a specific example, the third excitation magnetic field Br3 has a same magnetic field intensity as the first excitation magnetic field Br1. In a specific example, the third excitation magnetic field Br3 is identical to the first excitation magnetic field Br1.

In the example, the operation unit 800 is specifically configured to determine the magnetic field sensing signal of the magnetic field sensing device based on a difference between the value of the first sensing signal and the value of the second sensing signal. The magnetic field sensing signal includes a differential magnetic field signal corresponding to the first region S1 and the second region S2.

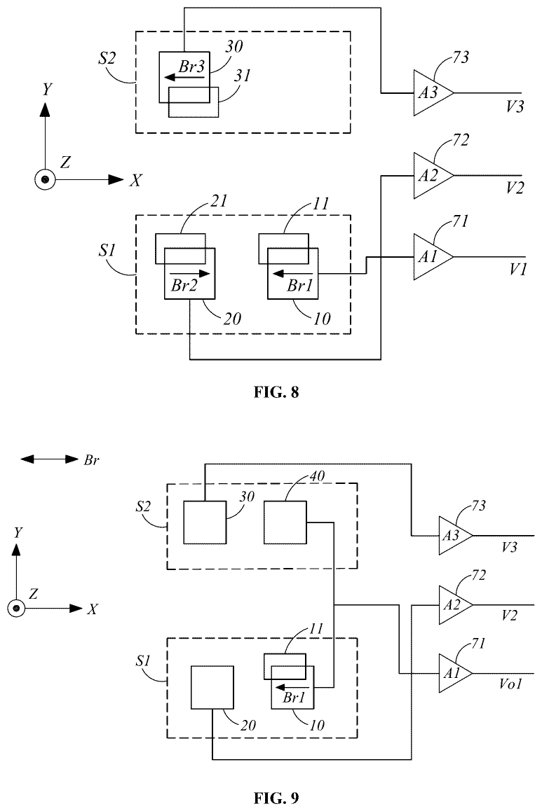

FIG. 8 shows a fourth example of the present application. The differences between the fourth example and the technical solution shown in FIG. 1 will be explained below, while similar aspects will not be repeated.

The magnetic field sensing device comprises a second magnetic field generating unit 21.

The second magnetic field generating unit 21 is configured to apply a predetermined second excitation magnetic field Br2 to the second sensing unit 20. The direction and magnetic field intensity of the second excitation magnetic field Br2 are predetermined and known.

The second magnetic field generating unit 21 may be configured as structures such as a coil, magnet, or other structures capable of generating local magnetic fields to apply the second excitation magnetic field Br2.

The second magnetic field generating unit 21 may be arranged close to the second sensing unit 20 to apply the second excitation magnetic field Br2 to the second sensing unit 20.

Correspondingly, the ambient magnetic field sensed by the second sensing unit 20 includes the second excitation magnetic field Br2.

The second excitation magnetic field Br2 has a direction opposite to the first excitation magnetic field Br1. Specifically, the second excitation magnetic field Br2 has a direction opposite to and equal intensity as the first excitation magnetic field Br1.

The second magnetic field generating unit 21 may be configured as shown in the second example in FIG. 6.

The magnetic field sensing device comprises a third magnetic field generating unit 31.

The third magnetic field generating unit 31 is configured to apply a predetermined third excitation magnetic field Br3 to the third sensing unit 30. The direction and magnetic field intensity of the third excitation magnetic field Br3 are predetermined and known.

The third magnetic field generating unit 31 may be configured as structures such as a coil, magnet, or other structures capable of generating local magnetic fields to apply the third excitation magnetic field Br3.

The third magnetic field generating unit 31 may be arranged close to the third sensing unit 30 to apply the third excitation magnetic field Br3 to the third sensing unit 30.

The third excitation magnetic field Br3 has a same direction as the first excitation magnetic field Br1. Specifically, the third excitation magnetic field Br3 has a same direction and equal intensity as the first excitation magnetic field Br1.

The third magnetic field generating unit 31 may be configured as shown in the third example in FIG. 7.

The magnetic field sensing device comprises a third sensing unit 30.

The third sensing unit 30 is arranged in the second region S2.

The third sensing unit 30 is configured to sense an ambient magnetic field to generate a third sensing signal.

The ambient magnetic field sensed by the third sensing unit 30 includes either the overall ambient magnetic field of the environment where the magnetic field sensing device is located, or the magnetic field component of the overall ambient magnetic field at the second region S2.

The third sensing unit 30 may be configured as shown in the first example in FIG. 5.

In combination with FIG. 1, in a specific example, the operation unit 800 determines a magnetic field sensing signal of the magnetic field sensing device based on a sum of the value of the second sensing signal and the value of the third sensing signal. The magnetic field sensing signal includes a common-mode sensing signal.

For example, define the value of the second sensing signal as V2, the value of the first signal magnetic field as Vsig1, the value of the second excitation magnetic field as Vbr2, the value of the third sensing signal as V3, the value of the second signal magnetic field as Vsig2, and the value of the third excitation magnetic field as Vbr3. When the first direction X is defined as the positive direction and Vbr2=Vbr3, the value of the common-mode sensing signal Vcom satisfies:

$$V 2 + V 3 = ( Vsig 1 + Vbr 2 ) + ( Vsig 2 - Vbr 3 ) = Vsig 1 + Vsig 2 = Vcom .$$

Wherein, the first signal magnetic field and the second signal magnetic field are not restricted and may have components in the first direction or its opposite direction.

In a specific example, the operation unit 800 determines a magnetic field sensing signal of the magnetic field sensing device based on a sum of the value of the first sensing signal and the value of the second sensing signal. The magnetic field sensing signal includes information of the first signal magnetic field.

For example, define the value of the first sensing signal as V1, the value of the first excitation magnetic field as Vbr1. When the first direction X is defined as the positive direction and Vbr1=Vbr2, the value of the first signal magnetic field Vsig1 satisfies:

$$V 1 + V 2 = ( Vsig 1 - Vbr 1 ) + ( Vsig 1 + Vbr 2 ) = 2 Vsig 1.$$

In a specific example, the operation unit 800 determines the calibration signal based on a difference between the value of the second sensing signal and the value of the first sensing signal.

For example, when the first direction X is defined as the positive direction and Vbr1=Vbr2, the value of the calibration signal Vref satisfies:

$$V 2 - V 1 = ( Vsig 1 + Vbr 2 ) - ( Vsig 1 - Vbr 1 ) = 2 Vbr 1 = Vref .$$

In a specific example, the operation unit 800 determines a magnetic field sensing signal of the magnetic field sensing device based on a difference between the value of the third sensing signal and the value of the first sensing signal. The magnetic field sensing signal includes a differential sensing signal.

For example, when the first direction X is defined as the positive direction and Vbr1=Vbr3, the value of the differential sensing signal Vdiff satisfies:

$$V 3 - V 1 = ( Vsig 2 - Vbr 3 ) - ( Vsig 1 - Vbr 1 ) = Vsig 2 - Vsig 1 = Vdiff .$$

FIG. 9 shows a fifth example of the present application. The differences between the fifth example and the first example shown in FIG. 5 will be explained below, while similar aspects will not be repeated.

The magnetic field sensing device comprises a fourth sensing unit 40.

The fourth sensing unit 40 is arranged in the second region S2. The fourth sensing unit 40 may be arranged at a same location as the third sensing unit 30, or may be arranged at a position close to the third sensing unit 30 within the second region S2.

The fourth sensing unit 40 is configured to sense an ambient magnetic field to generate a fourth sensing signal.

The ambient magnetic field sensed by the fourth sensing unit 40 includes either the overall ambient magnetic field of the environment where the magnetic field sensing device is located, or the magnetic field component of the overall ambient magnetic field at the second region S2.

In a specific example, the magnetic field sensing device comprises a first amplifier 71, an input terminal of the first amplifier 71 is coupled to the first sensing unit 10 and the fourth sensing unit 40, and an output terminal of the first amplifier 71 is configured to generate a first intermediate output.

In combination with FIG. 1, the operation unit 800 is configured to determine the calibration signal based on a value of the first sensing signal and a value of the fourth sensing signal; the operation unit 800 is configured to determine the calibration signal based on a value of the second sensing signal and a value of the third sensing signal.

In a specific example, the operation unit 800 is configured to determine the calibration signal based on a difference between the value of the first sensing signal and the value of the fourth sensing signal, and a difference between the value of the second sensing signal and the value of the third sensing signal.

For example, define the value of the fourth sensing signal as V4, define the value of the first intermediate output as Vo1 (Vo1=V4−V1), when the first direction X is defined as the positive direction and Vbr1=Vbr2, the value of the calibration signal Vref satisfies:

$$Vo 1 - ( V 3 - V 2 ) = ( V 4 - V 1 ) - ( V 3 - V 2 ) = ( Vsig 1 - Vbr 1 - Vsig 2 ) - ( Vsig 2 - Vsig 1 ) = - Vbr 1 = Vref$$

In a specific example, the operation unit 800 is configured to determine the calibration signal based on a sum of the value of the first sensing signal and the value of the fourth sensing signal, and a sum of the value of the second sensing signal and the value of the third sensing signal.

For example, define the value of the fourth sensing signal as V4, define the value of the first intermediate output as Vo1 (Vo1=V4−V1), when the first direction X is defined as the positive direction and Vbr1=Vbr2, the value of the calibration signal Vref satisfies:

$$Vo 1 - ( V 2 - V 3 ) = ( V 4 + V 1 ) - ( V 2 + V 3 ) = ( Vsig 2 + Vsig 1 - Vbr 1 ) - ( Vsig 2 + Vsig 1 ) = - Vbr 1 = Vref$$

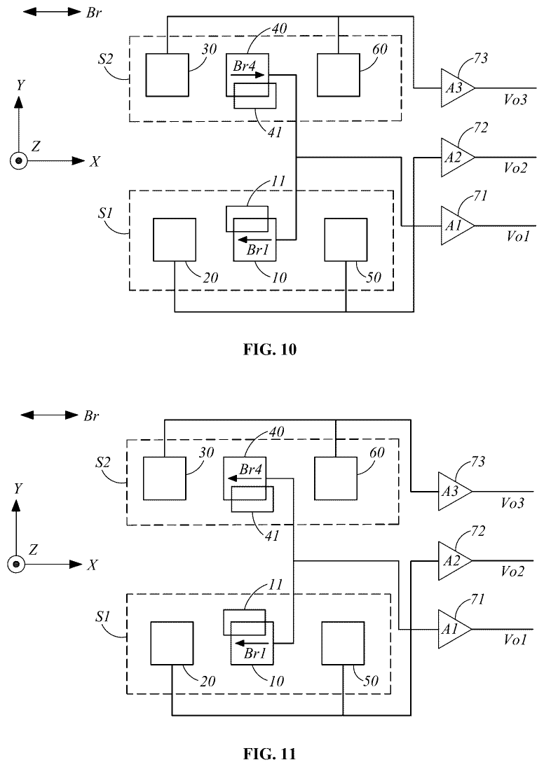

FIG. 10 shows a sixth example of the present application. The differences between the sixth example and the fifth example shown in FIG. 9 will be explained below, while similar aspects will not be repeated.

The magnetic field sensing device comprises a fifth sensing unit 50.

The fifth sensing unit 50 is arranged in the first region S1. The fifth sensing unit 50 may be arranged at a same location as the first sensing unit 10, or may be arranged at a position close to the first sensing unit 10 within the first region S1. The fifth sensing unit 50 may be arranged at a same location as the second sensing unit 20, or may be arranged at a position close to the second sensing unit 20 within the first region S1.

The fifth sensing unit 50 is configured to sense an ambient magnetic field to generate a fifth sensing signal.

The ambient magnetic field sensed by the fifth sensing unit 50 includes either the overall ambient magnetic field of the environment where the magnetic field sensing device is located, or the magnetic field component of the overall ambient magnetic field at the first region S1.

In a specific example, the magnetic field sensing device comprises a second amplifier 72, an input terminal of the second amplifier 72 is coupled to the second sensing unit 20 and the fifth sensing unit 50, and an output terminal of the second amplifier 72 is configured to generate a second intermediate output.

The magnetic field sensing device comprises a sixth sensing unit 60.

The sixth sensing unit 60 is arranged in the second region S2. The sixth sensing unit 60 may be arranged at a same location as the third sensing unit 30, or may be arranged at a position close to the third sensing unit 30 within the second region S2. The sixth sensing unit 60 may be arranged at a same location as the fourth sensing unit 40, or may be arranged at a position close to the fourth sensing unit 40 within the second region S2.

The sixth sensing unit 60 is configured to sense an ambient magnetic field to generate a sixth sensing signal.

The ambient magnetic field sensed by the sixth sensing unit 60 includes either the overall ambient magnetic field of the environment where the magnetic field sensing device is located, or the magnetic field component of the overall ambient magnetic field at the second region S2.

In a specific example, the magnetic field sensing device comprises a third amplifier 73, an input terminal of the third amplifier 73 is coupled to the third sensing unit 30 and the sixth sensing unit 60, and an output terminal of the third amplifier 73 is configured to generate a third intermediate output.

In combination with FIG. 1, the operation unit 800 is configured to determine a magnetic field sensing signal of the magnetic field sensing device based on a value of the second sensing signal and a value of the fifth sensing signal; the operation unit 800 is configured to determine a magnetic field sensing signal of the magnetic field sensing device based on a value of the third sensing signal and a value of the sixth sensing signal.

In a specific example, the operation unit 800 is configured to determine a magnetic field sensing signal of the magnetic field sensing device based on a sum of the value of the second sensing signal and the value of the fifth sensing signal, and a sum of the value of the third sensing signal and the value of the sixth sensing signal.

The magnetic field sensing signal includes a differential sensing signal corresponding to the first region S1 and the second region S2, and/or includes a common-mode sensing signal corresponding to the first region S1 and the second region S2.

For example, define the value of the fifth sensing signal as V5, the value of the sixth sensing signal as V6, the value of the second intermediate output as Vo2 (Vo2=V2+V5), the value of the third intermediate output as Vo3 (Vo3=V3+V6), then the value of the common-mode sensing signal Vcom satisfies:

$$Vo 2 + Vo 3 = V 2 + V 5 + V 3 + V 6 = 2 ( Vsig 1 + Vsig 2 ) = Vcom$$

The value of the differential sensing signal Vdiff satisfies:

$$Vo 3 - Vo 2 = ( V 3 + V 6 ) - ( V 2 + V 5 ) = 2 ( Vsig 2 - Vsig 1 ) = Vdiff$$

In a specific example, the magnetic field sensing device comprises a fourth magnetic field generating unit 41.

The fourth magnetic field generating unit 41 is configured to apply a predetermined fourth excitation magnetic field Br4 to the fourth sensing unit 40. The direction and magnetic field intensity of the fourth excitation magnetic field Br4 are predetermined and known.

The fourth magnetic field generating unit 41 may be configured as structures such as a coil, magnet, or other structures capable of generating local magnetic fields to apply the fourth excitation magnetic field Br4.

The fourth magnetic field generating unit 41 may be arranged close to the fourth sensing unit 40 to apply the fourth excitation magnetic field Br4 to the fourth sensing unit 40.

The fourth excitation magnetic field Br4 applied by the fourth magnetic field generating unit 41 has at least a magnetic field component along the sensing direction of the fourth sensing unit 40. For example, when the fourth sensing unit 40 has a sensing direction along the first direction X or its opposite direction, the fourth magnetic field generating unit 41 applies the fourth excitation magnetic field Br4 in the first direction X to the fourth sensing unit 40.

Correspondingly, the ambient magnetic field sensed by the fourth sensing unit 40 includes the fourth excitation magnetic field Br4.

In a specific example, the ambient magnetic field sensed by the fourth sensing unit 40 includes the fourth excitation magnetic field Br4 and a second signal magnetic field corresponding to the second region S2.

In a specific example, the fourth sensing signal includes information corresponding to the second signal magnetic field and information corresponding to the fourth excitation magnetic field Br4.

The fourth excitation magnetic field Br4 has a direction opposite to the first excitation magnetic field Br1. In a specific example, the fourth excitation magnetic field Br4 has a same magnetic field intensity as the first excitation magnetic field Br1.

In combination with FIG. 1, the operation unit 800 is configured to determine the calibration signal based on a value of the first sensing signal and a value of the fourth sensing signal; the operation unit 800 is configured to determine the calibration signal based on a value of the second sensing signal and a value of the fifth sensing signal; the operation unit 800 is configured to determine the calibration signal based on a value of the third sensing signal and a value of the sixth sensing signal.

In a specific example, the operation unit 800 is configured to determine the calibration signal based on a difference between the value of the first sensing signal and the value of the fourth sensing signal, a sum of the value of the second sensing signal and the value of the fifth sensing signal, and a sum of the value of the first sensing signal and the value of the fourth sensing signal.

For example, define the value of the fourth excitation magnetic field as Vbr4, when the first direction X is defined as the positive direction and Vbr1=Vbr4, the value of the calibration signal Vref satisfies:

$$Vo 3 - Vo 2 + 2 Vo 1 = ( Vsig 2 + Vsig 2 ) - ( Vsig 1 + Vsig 1 ) + 2 ( ( Vsig 1 + Vbr 1 ) - ( Vsig 2 - Vbr 4 ) ) = - 4 Vbr 1 = Vref$$

FIG. 11 shows a seventh example of the present application. The differences between the seventh example and the sixth example shown in FIG. 10 will be explained below, while similar aspects will not be repeated.

The fourth excitation magnetic field Br4 has a same direction as the first excitation magnetic field Br1. In a specific example, the fourth excitation magnetic field Br4 has a same magnetic field intensity as the first excitation magnetic field Br1. In a specific example, the fourth excitation magnetic field Br4 is identical to the first excitation magnetic field Br1.

In combination with FIG. 1, the operation unit 800 is configured to determine the calibration signal based on a value of the first sensing signal and a value of the fourth sensing signal; the operation unit 800 is configured to determine the calibration signal based on a value of the second sensing signal and a value of the fifth sensing signal; the operation unit 800 is configured to determine the calibration signal based on a value of the third sensing signal and a value of the sixth sensing signal.

The operation unit 800 is configured to determine the calibration signal based on a sum of the value of the first sensing signal and the value of the fourth sensing signal, a sum of the value of the second sensing signal and the value of the fifth sensing signal, and a sum of the value of the first sensing signal and the value of the fourth sensing signal.

For example, when the first direction X is defined as the positive direction and Vbr1=Vbr4, the value of the calibration signal Vref satisfies:

$$Vo 3 - Vo 2 + 2 Vo 1 = ( Vsig 2 + Vsig 2 ) - ( Vsig 1 + Vsig 1 ) + 2 ( ( Vsig 2 - Vbr 1 ) + ( Vsig 1 - Vbr 4 ) ) = - 4 Vbr 1 = Vref$$

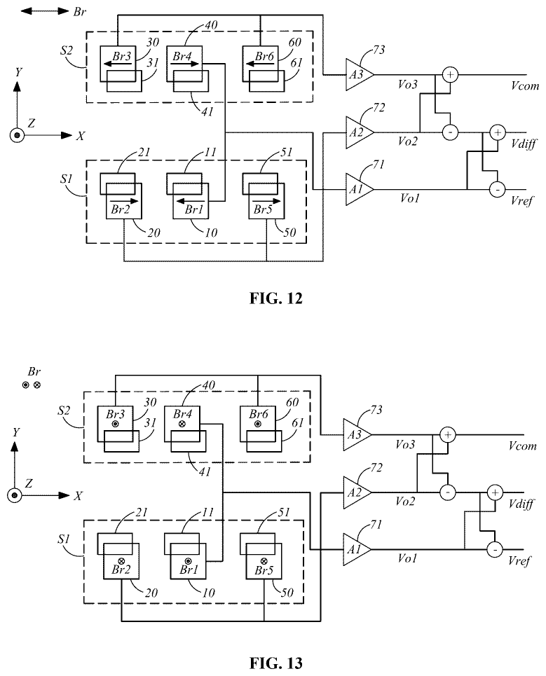

FIG. 12 shows an eighth example of the present application. The differences between the eighth example and the sixth example shown in FIG. 10 and the seventh example shown in FIG. 11 will be explained below, while similar aspects will not be repeated.

The magnetic field sensing device comprises a second magnetic field generating unit 21.

The second magnetic field generating unit 21 is configured to apply a predetermined second excitation magnetic field Br2 to the second sensing unit 20. The direction and magnetic field intensity of the second excitation magnetic field Br2 are predetermined and known.

The second magnetic field generating unit 21 may be configured as structures such as a coil, magnet, or other structures capable of generating local magnetic fields to apply the second excitation magnetic field Br2.

The second magnetic field generating unit 21 may be arranged close to the second sensing unit 20 to apply the second excitation magnetic field Br2 to the second sensing unit 20.

Correspondingly, the ambient magnetic field sensed by the second sensing unit 20 includes the second excitation magnetic field Br2.

In a specific example, the second excitation magnetic field Br2 has a direction opposite to the first excitation magnetic field Br1. Specifically, the second excitation magnetic field Br2 has a direction opposite to and equal intensity as the first excitation magnetic field Br1.

The second magnetic field generating unit 21 may be configured as shown in the second example in FIG. 6.

The magnetic field sensing device comprises a third magnetic field generating unit 31.

The third magnetic field generating unit 31 is configured to apply a predetermined third excitation magnetic field Br3 to the third sensing unit 30. The direction and magnetic field intensity of the third excitation magnetic field Br3 are predetermined and known.

The third magnetic field generating unit 31 may be configured as structures such as a coil, magnet, or other structures capable of generating local magnetic fields to apply the third excitation magnetic field Br3.

The third magnetic field generating unit 31 may be arranged close to the third sensing unit 30 to apply the third excitation magnetic field Br3 to the third sensing unit 30.

Correspondingly, the ambient magnetic field sensed by the third sensing unit 30 includes the third excitation magnetic field Br3.

In a specific example, the third excitation magnetic field Br3 has a direction opposite to the second excitation magnetic field Br2. Specifically, the third excitation magnetic field Br3 has a direction opposite to and equal intensity as the second excitation magnetic field Br2.

In a specific example, the third excitation magnetic field Br3 has a same direction as the first excitation magnetic field Br1. Specifically, the third excitation magnetic field Br3 has a same direction and equal intensity as the first excitation magnetic field Br1.

The third magnetic field generating unit 31 may be configured as shown in the third example in FIG. 7.

The magnetic field sensing device comprises a fourth magnetic field generating unit 41.

The fourth magnetic field generating unit 41 is configured to apply a predetermined fourth excitation magnetic field Br4 to the fourth sensing unit 40. The direction and magnetic field intensity of the fourth excitation magnetic field Br4 are predetermined and known.

The fourth magnetic field generating unit 41 may be configured as structures such as a coil, magnet, or other structures capable of generating local magnetic fields to apply the fourth excitation magnetic field Br4.

The fourth magnetic field generating unit 41 may be arranged close to the fourth sensing unit 40 to apply the fourth excitation magnetic field Br4 to the fourth sensing unit 40.

Correspondingly, the ambient magnetic field sensed by the fourth sensing unit 40 includes the fourth excitation magnetic field Br4.

In a specific example, the fourth excitation magnetic field Br4 has a direction opposite to the first excitation magnetic field Br1. Specifically, the fourth excitation magnetic field Br4 has a direction opposite to and equal intensity as the first excitation magnetic field Br1.

The fourth magnetic field generating unit 41 may be configured as shown in the sixth example in FIG. 10 and the seventh example in FIG. 11.

The magnetic field sensing device comprises a fifth magnetic field generating unit 51.

The fifth magnetic field generating unit 51 is configured to apply a predetermined fifth excitation magnetic field Br5 to the fifth sensing unit 50. The direction and magnetic field intensity of the fifth excitation magnetic field Br5 are predetermined and known.

The fifth magnetic field generating unit 51 may be configured as structures such as a coil, magnet, or other structures capable of generating local magnetic fields to apply the fifth excitation magnetic field Br5.

The fifth magnetic field generating unit 51 may be arranged close to the fifth sensing unit 50 to apply the fifth excitation magnetic field Br5 to the fifth sensing unit 50.

The fifth excitation magnetic field Br5 applied by the fifth magnetic field generating unit 51 has at least a magnetic field component along the sensing direction of the fifth sensing unit 50. For example, when the fifth sensing unit 50 has a sensing direction along the first direction X or its opposite direction, the fifth magnetic field generating unit 51 applies the fifth excitation magnetic field Br5 in the first direction X to the fifth sensing unit 50.

Correspondingly, the ambient magnetic field sensed by the fifth sensing unit 50 includes the fifth excitation magnetic field Br5.

In a specific example, the ambient magnetic field sensed by the fifth sensing unit 50 includes the fifth excitation magnetic field Br5 and a first signal magnetic field corresponding to the first region S1.

In a specific example, the fifth sensing signal includes information corresponding to the first signal magnetic field and information corresponding to the fifth excitation magnetic field Br5.

In a specific example, the fifth excitation magnetic field Br5 has a direction opposite to the first excitation magnetic field Br1. Specifically, the fifth excitation magnetic field Br5 has a same magnetic field intensity as the first excitation magnetic field Br1.

In a specific example, the fifth excitation magnetic field Br5 has a same direction as the second excitation magnetic field Br2. Specifically, the fifth excitation magnetic field Br5 has a same magnetic field intensity as the second excitation magnetic field Br2.

The magnetic field sensing device comprises a sixth magnetic field generating unit 61.

The sixth magnetic field generating unit 61 is configured to apply a predetermined sixth excitation magnetic field Br6 to the sixth sensing unit 60. The direction and magnetic field intensity of the sixth excitation magnetic field Br6 are predetermined and known.

The sixth magnetic field generating unit 61 may be configured as structures such as a coil, magnet, or other structures capable of generating local magnetic fields to apply the sixth excitation magnetic field Br6.

The sixth magnetic field generating unit 61 may be arranged close to the sixth sensing unit 60 to apply the sixth excitation magnetic field Br6 to the sixth sensing unit 60.

The sixth excitation magnetic field Br6 applied by the sixth magnetic field generating unit 61 has at least a magnetic field component along the sensing direction of the sixth sensing unit 60. For example, when the sixth sensing unit 60 has a sensing direction along the first direction X or its opposite direction, the sixth magnetic field generating unit 61 applies the sixth excitation magnetic field Br6 in the opposite direction of the first direction X to the sixth sensing unit 60.

Correspondingly, the ambient magnetic field sensed by the sixth sensing unit 60 includes the sixth excitation magnetic field Br6.

In a specific example, the ambient magnetic field sensed by the sixth sensing unit 60 includes the sixth excitation magnetic field Br6 and a second signal magnetic field corresponding to the second region S2.

In a specific example, the sixth sensing signal includes information corresponding to the second signal magnetic field and information corresponding to the sixth excitation magnetic field Br6.

In a specific example, the sixth excitation magnetic field Br6 has a same direction as the first excitation magnetic field Br1. Specifically, the sixth excitation magnetic field Br6 has a same magnetic field intensity as the first excitation magnetic field Br1.

In a specific example, the sixth excitation magnetic field Br6 has a same direction as the third excitation magnetic field Br3. Specifically, the sixth excitation magnetic field Br6 has a same magnetic field intensity as the third excitation magnetic field Br3.

In combination with FIG. 1, the operation unit 800 is configured to determine a magnetic field sensing signal of the magnetic field sensing device based on a value of the second sensing signal and a value of the fifth sensing signal; the operation unit 800 is configured to determine a magnetic field sensing signal of the magnetic field sensing device based on a value of the third sensing signal and a value of the sixth sensing signal.

In a specific example, the operation unit 800 is configured to determine a magnetic field sensing signal of the magnetic field sensing device based on a sum of the value of the second sensing signal and the value of the fifth sensing signal, and a sum of the value of the third sensing signal and the value of the sixth sensing signal.

The magnetic field sensing signal includes a common-mode sensing signal corresponding to the first region S1 and the second region S2.

For example, define the value of the fifth excitation magnetic field as Vbr5, the value of the sixth excitation magnetic field as Vbr6, when the first direction X is defined as the positive direction and Vbr2+Vbr5=Vbr3+Vbr6, the value of the common-mode sensing signal Vcom satisfies:

$$Vo 2 + Vo 3 = ( ( Vsig 1 + Vbr 2 ) + ( Vsig 1 + Vbr 5 ) ) + ( ( Vsig 2 - Vbr 3 ) + ( Vsig 2 - Vbr 6 ) ) = 2 ( Vsig 1 + Vsig 2 ) = Vcom$$

Preferably, Vbr2=Vbr3=Vbr5=Vbr6.

In combination with FIG. 1, the operation unit 800 is configured to determine a magnetic field sensing signal of the magnetic field sensing device based on a value of the second sensing signal and a value of the fifth sensing signal; the operation unit 800 is configured to determine a magnetic field sensing signal of the magnetic field sensing device based on a value of the third sensing signal and a value of the sixth sensing signal; the operation unit 800 is configured to determine a magnetic field sensing signal of the magnetic field sensing device based on a value of the first sensing signal and a value of the fourth sensing signal.

In a specific example, the operation unit 800 is configured to determine a magnetic field sensing signal of the magnetic field sensing device based on a sum of the value of the second sensing signal and the value of the fifth sensing signal, a sum of the value of the third sensing signal and the value of the sixth sensing signal, and a difference between the value of the first sensing signal and the value of the fourth sensing signal.

The magnetic field sensing signal includes a differential sensing signal corresponding to the first region S1 and the second region S2.

For example, when the first direction X is defined as the positive direction and Vbr3+Vbr6+Vbr2+Vbr5=2Vbr4+2Vbr1, the value of the differential sensing signal Vdiff satisfies:

$$Vo 2 - Vo 3 + 2 Vo 1 = ( ( Vsig 1 + Vbr 2 ) + ( Vsig 1 + Vbr 5 ) ) - ( ( Vsig 2 - Vbr 3 ) + ( Vsig 2 - Vbr 6 ) ) + 2 ( ( Vsig 1 - Vbr 1 ) - ( Vsig 2 + Vbr 4 ) ) = - 4 ( Vsig 2 - Vsig 1 ) = Vdiff$$

Preferably, Vbr1=Vbr2=Vbr3=Vbr4=Vbr5=Vbr6.

In combination with FIG. 1, the operation unit 800 is configured to determine the calibration signal based on a value of the second sensing signal and a value of the fifth sensing signal; the operation unit 800 is configured to determine the calibration signal based on a value of the third sensing signal and a value of the sixth sensing signal; the operation unit 800 is configured to determine the calibration signal based on a value of the first sensing signal and a value of the fourth sensing signal.

In a specific example, the operation unit 800 is configured to determine the calibration signal based on a sum of the value of the second sensing signal and the value of the fifth sensing signal, a sum of the value of the third sensing signal and the value of the sixth sensing signal, and a difference between the value of the first sensing signal and the value of the fourth sensing signal.

For example, when the first direction X is defined as the positive direction and Vbr1=Vbr2=Vbr3=Vbr4=Vbr5=Vbr6, the calibration signal Vref satisfies:

$$Vo 2 - Vo 3 - 2 Vo 1 = ( ( Vsig 1 + Vbr 2 ) + ( Vsig 1 + Vbr 5 ) ) - ( ( Vsig 2 - Vbr 3 ) + ( Vsig 2 - Vbr 6 ) ) - 2 ( ( Vsig 1 - Vbr 1 ) - ( Vsig 2 + Vbr 4 ) ) = 8 Vbr 1 = Vref$$

In a specific example, the magnetic field sensing device further comprises adders and/or subtractors, configured to implement above-mentioned addition and subtraction operations. The adders and/or subtractors may be included in the operation unit 800, with the operation unit 800 implementing the above operations based on adders and subtractors; alternatively, the adders and/or subtractors may replace the operation unit 800 to implement the above operations.

Specifically, the magnetic field sensing device comprises a first adder, with a first input terminal coupled to the third intermediate output (for example, coupled to the third sensing unit 30 and the sixth sensing unit 60), a second input terminal coupled to the second intermediate output (for example, coupled to the second sensing unit 20 and the fifth sensing unit 50), and an output terminal configured to generate the common-mode sensing signal.

The magnetic field sensing device comprises a third amplifier 73 and a second amplifier 72, with a first input terminal of the first adder coupled to an output terminal of the third amplifier 73, and a second input terminal of the first adder coupled to an output terminal of the second amplifier 72.

Specifically, the magnetic field sensing device comprises a first subtractor and a second adder. A first input terminal of the first subtractor is coupled to the third intermediate output (for example, coupled to the third sensing unit 30 and the sixth sensing unit 60), and a second input terminal of the first subtractor is coupled to the second intermediate output (for example, coupled to the second sensing unit 20 and the fifth sensing unit 50). A first input terminal of the second adder is coupled to an output terminal of the first subtractor, a second input terminal of the second adder is coupled to the first intermediate output (for example, coupled to the first sensing unit 10 and the fourth sensing unit 40), and an output terminal of the second adder is configured to generate the differential sensing signal.

The magnetic field sensing device comprises a third amplifier 73, a second amplifier 72, and a first amplifier 71, with a first input terminal of the first subtractor coupled to an output terminal of the third amplifier 73, a second input terminal of the first subtractor coupled to an output terminal of the second amplifier 72, a first input terminal of the second adder coupled to an output terminal of the first subtractor, and a second input terminal of the second adder coupled to an output terminal of the first amplifier 71.

Specifically, the magnetic field sensing device comprises a second subtractor, with a first input terminal coupled to an output terminal of the first subtractor, a second input terminal coupled to the first intermediate output (for example, coupled to the first sensing unit 10 and the fourth sensing unit 40), and an output terminal configured to generate the calibration signal.

FIG. 13 shows a ninth example of the present application. The differences between the ninth example and the eighth example shown in FIG. 12 will be explained below, while similar aspects will not be repeated.

In the ninth example shown in FIG. 13, the sensing units have sensing directions along the first direction X or its opposite direction.

Specifically, the first sensing unit 10 has at least a sensing direction along the opposite direction of the first direction X; the second sensing unit 20 has at least a sensing direction along the first direction X; the third sensing unit 30 has at least a sensing direction along the opposite direction of the first direction X; the fourth sensing unit 40 has at least a sensing direction along the first direction X; the fifth sensing unit 50 has at least a sensing direction along the first direction X; the sixth sensing unit 60 has at least a sensing direction along the opposite direction of the first direction X.

In other examples, the sensing units have sensing directions along the first direction X or its opposite direction.

In other examples, the sensing units have sensing directions parallel to their respective planes. For example, the first sensing unit 10 has a sensing direction parallel to the plane where the first sensing unit 10 is located; the second sensing unit 20 has a sensing direction parallel to the plane where the second sensing unit 20 is located.

In the ninth example shown in FIG. 13, the sensing units have sensing directions perpendicular to a plane where they arranged; the sensing units have sensing directions along the third direction Z or its opposite direction.

Specifically, the first sensing unit 10 has at least a sensing direction along the third direction Z; the second sensing unit 20 has at least a sensing direction along the opposite direction of the third direction Z; the third sensing unit 30 has at least a sensing direction along the third direction Z; the fourth sensing unit 40 has at least a sensing direction along the opposite direction of the third direction Z; the fifth sensing unit 50 has at least a sensing direction along the opposite direction of the third direction Z; the sixth sensing unit 60 has at least a sensing direction along the third direction Z.

The first magnetic field generating unit 11 is configured to apply a predetermined first excitation magnetic field Br1 to the first sensing unit 10. The first excitation magnetic field Br1 is along the third direction Z.

The second magnetic field generating unit 21 is configured to apply a predetermined second excitation magnetic field Br2 to the second sensing unit 20. The second excitation magnetic field Br2 is along the opposite direction of the third direction Z.

The third magnetic field generating unit 31 is configured to apply a predetermined third excitation magnetic field Br3 to the third sensing unit 30. The third excitation magnetic field Br3 is along the third direction Z.

The fourth magnetic field generating unit 41 is configured to apply a predetermined fourth excitation magnetic field Br4 to the fourth sensing unit 40. The fourth excitation magnetic field Br4 is along the opposite direction of the third direction Z.

The fifth magnetic field generating unit 51 is configured to apply a predetermined fifth excitation magnetic field Br5 to the fifth sensing unit 50. The fifth excitation magnetic field Br5 is along the opposite direction of the third direction Z.

The sixth magnetic field generating unit 61 is configured to apply a predetermined sixth excitation magnetic field Br6 to the sixth sensing unit 60. The sixth excitation magnetic field Br6 is along the third direction Z.

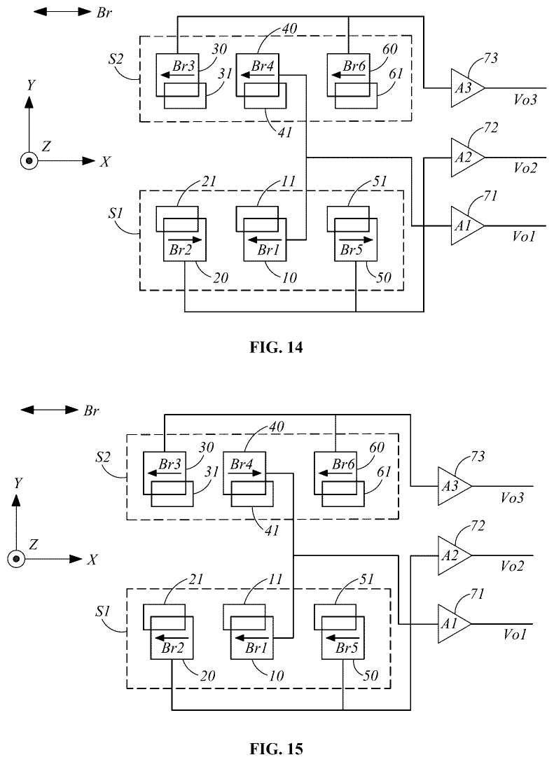

FIG. 14 shows a tenth example of the present application. The differences between the tenth example and the sixth example shown in FIG. 10 and the seventh example shown in FIG. 11 will be explained below, while similar aspects will not be repeated.

The magnetic field sensing device comprises a second magnetic field generating unit 21.

The second magnetic field generating unit 21 is configured to apply a predetermined second excitation magnetic field Br2 to the second sensing unit 20. The direction and magnetic field intensity of the second excitation magnetic field Br2 are predetermined and known.

The second magnetic field generating unit 21 may be configured as structures such as a coil, magnet, or other structures capable of generating local magnetic fields to apply the second excitation magnetic field Br2.

The second magnetic field generating unit 21 may be arranged close to the second sensing unit 20 to apply the second excitation magnetic field Br2 to the second sensing unit 20.

Correspondingly, the ambient magnetic field sensed by the second sensing unit 20 includes the second excitation magnetic field Br2.

In a specific example, the second excitation magnetic field Br2 has a direction opposite to the first excitation magnetic field Br1. Specifically, the second excitation magnetic field Br2 has a direction opposite to and equal intensity as the first excitation magnetic field Br1.

The second magnetic field generating unit 21 may be configured as shown in the second example in FIG. 6.

The magnetic field sensing device comprises a third magnetic field generating unit 31.

The third magnetic field generating unit 31 is configured to apply a predetermined third excitation magnetic field Br3 to the third sensing unit 30. The direction and magnetic field intensity of the third excitation magnetic field Br3 are predetermined and known.

The third magnetic field generating unit 31 may be configured as structures such as a coil, magnet, or other structures capable of generating local magnetic fields to apply the third excitation magnetic field Br3.

The third magnetic field generating unit 31 may be arranged close to the third sensing unit 30 to apply the third excitation magnetic field Br3 to the third sensing unit 30.

Correspondingly, the ambient magnetic field sensed by the third sensing unit 30 includes the third excitation magnetic field Br3.

In a specific example, the third excitation magnetic field Br3 has a direction opposite to the second excitation magnetic field Br2. Specifically, the third excitation magnetic field Br3 has a direction opposite to and equal intensity as the second excitation magnetic field Br2.

In a specific example, the third excitation magnetic field Br3 has a same direction as the first excitation magnetic field Br1. Specifically, the third excitation magnetic field Br3 has a same direction and equal intensity as the first excitation magnetic field Br1.

The third magnetic field generating unit 31 may be configured as shown in the third example in FIG. 7.

The magnetic field sensing device comprises a fourth magnetic field generating unit 41.

The fourth magnetic field generating unit 41 is configured to apply a predetermined fourth excitation magnetic field Br4 to the fourth sensing unit 40. The direction and magnetic field intensity of the fourth excitation magnetic field Br4 are predetermined and known.

The fourth magnetic field generating unit 41 may be configured as structures such as a coil, magnet, or other structures capable of generating local magnetic fields to apply the fourth excitation magnetic field Br4.

The fourth magnetic field generating unit 41 may be arranged close to the fourth sensing unit 40 to apply the fourth excitation magnetic field Br4 to the fourth sensing unit 40.

Correspondingly, the ambient magnetic field sensed by the fourth sensing unit 40 includes the fourth excitation magnetic field Br4.

In a specific example, the fourth excitation magnetic field Br4 has a same direction as the first excitation magnetic field Br1. Specifically, the fourth excitation magnetic field Br4 has a same direction and equal intensity as the first excitation magnetic field Br1.

The fourth magnetic field generating unit 41 may be configured as shown in the sixth example in FIG. 10 and the seventh example in FIG. 11.

The magnetic field sensing device comprises a fifth magnetic field generating unit 51.

The fifth magnetic field generating unit 51 is configured to apply a predetermined fifth excitation magnetic field Br5 to the fifth sensing unit 50. The direction and magnetic field intensity of the fifth excitation magnetic field Br5 are predetermined and known.

The fifth magnetic field generating unit 51 may be configured as structures such as a coil, magnet, or other structures capable of generating local magnetic fields to apply the fifth excitation magnetic field Br5.

The fifth magnetic field generating unit 51 may be arranged close to the fifth sensing unit 50 to apply the fifth excitation magnetic field Br5 to the fifth sensing unit 50.

Correspondingly, the ambient magnetic field sensed by the fifth sensing unit 50 includes the fifth excitation magnetic field Br5.

In a specific example, the fifth excitation magnetic field Br5 has a same direction as the second excitation magnetic field Br2. Specifically, the fifth excitation magnetic field Br5 has a same magnetic field intensity as the second excitation magnetic field Br2.

In a specific example, the fifth excitation magnetic field Br5 has a direction opposite to the first excitation magnetic field Br1. Specifically, the fifth excitation magnetic field Br5 has a same magnetic field intensity as the first excitation magnetic field Br1.

The fifth magnetic field generating unit 51 may be configured as shown in the eighth example in FIG. 12.

The magnetic field sensing device comprises a sixth magnetic field generating unit 61.

The sixth magnetic field generating unit 61 is configured to apply a predetermined sixth excitation magnetic field Br6 to the sixth sensing unit 60. The direction and magnetic field intensity of the sixth excitation magnetic field Br6 are predetermined and known.

The sixth magnetic field generating unit 61 may be configured as structures such as a coil, magnet, or other structures capable of generating local magnetic fields to apply the sixth excitation magnetic field Br6.

The sixth magnetic field generating unit 61 may be arranged close to the sixth sensing unit 60 to apply the sixth excitation magnetic field Br6 to the sixth sensing unit 60.

Correspondingly, the ambient magnetic field sensed by the sixth sensing unit 60 includes the sixth excitation magnetic field Br6.

In a specific example, the sixth excitation magnetic field Br6 has a same direction as the third excitation magnetic field Br3. Specifically, the sixth excitation magnetic field Br6 has a same magnetic field intensity as the third excitation magnetic field Br3.

In a specific example, the sixth excitation magnetic field Br6 has a same direction as the first excitation magnetic field Br1. Specifically, the sixth excitation magnetic field Br6 has a same magnetic field intensity as the first excitation magnetic field Br1.

The sixth magnetic field generating unit 61 may be configured as shown in the eighth example in FIG. 12.

In combination with FIG. 1, the operation unit 800 is configured to determine a magnetic field sensing signal of the magnetic field sensing device based on a value of the second sensing signal and a value of the fifth sensing signal; the operation unit 800 is configured to determine a magnetic field sensing signal of the magnetic field sensing device based on a value of the third sensing signal and a value of the sixth sensing signal.

In a specific example, the operation unit 800 is configured to determine a magnetic field sensing signal of the magnetic field sensing device based on a sum of the value of the second sensing signal and the value of the fifth sensing signal, and a sum of the value of the third sensing signal and the value of the sixth sensing signal.

The magnetic field sensing signal includes a common-mode sensing signal corresponding to the first region S1 and the second region S2.

For example, when the first direction X is defined as the positive direction and Vbr2+Vbr5=Vbr3+Vbr6, the value of the common-mode sensing signal Vcom satisfies:

$$Vo 2 + Vo 3 = ( ( Vsig 1 + Vbr 2 ) + ( Vsig 1 + Vbr 5 ) ) + ( ( Vsig 2 - Vbr 3 ) + ( Vsig 2 - Vbr 6 ) ) = 2 ( Vsig 1 + Vsig 2 ) = Vcom$$

Preferably, Vbr2=Vbr3=Vbr5=Vbr6.

In combination with FIG. 1, the operation unit 800 is configured to determine a magnetic field sensing signal of the magnetic field sensing device based on a value of the second sensing signal and a value of the fifth sensing signal; the operation unit 800 is configured to determine a magnetic field sensing signal of the magnetic field sensing device based on a sum of the value of the first sensing signal and the value of the fourth sensing signal.

In a specific example, the operation unit 800 is configured to determine a magnetic field sensing signal of the magnetic field sensing device based on a sum of the value of the second sensing signal and the value of the fifth sensing signal, and a sum of the value of the first sensing signal and the value of the fourth sensing signal.

The magnetic field sensing signal includes a differential sensing signal corresponding to the first region S1 and the second region S2.

For example, when the first direction X is defined as the positive direction and Vbr3+Vbr6=Vbr4+Vbr1, the value of the differential sensing signal Vdiff satisfies:

$$Vo 3 - Vo 1 = ( ( Vsig 2 - Vbr 3 ) + ( Vsig 2 - Vbr 6 ) ) - ( ( Vsig 2 - Vbr 4 ) + ( Vsig 1 - Vbr 1 ) ) = Vsig 2 - Vsig 1 = Vdiff$$

Preferably, Vbr1=Vbr3=Vbr4=Vbr6.

In combination with FIG. 1, the operation unit 800 is configured to determine the calibration signal based on a value of the second sensing signal and a value of the fifth sensing signal; the operation unit 800 is configured to determine the calibration signal based on a value of the third sensing signal and a value of the sixth sensing signal; the operation unit 800 is configured to determine the calibration signal based on a value of the first sensing signal and a value of the fourth sensing signal.

In a specific example, the operation unit 800 is configured to determine the calibration signal based on a sum of the value of the second sensing signal and the value of the fifth sensing signal, a sum of the value of the third sensing signal and the value of the sixth sensing signal, and a sum of the value of the first sensing signal and the value of the fourth sensing signal.

For example, when the first direction X is defined as the positive direction and Vbr1=Vbr2=Vbr3=Vbr4=Vbr5=Vbr6, the calibration signal Vref satisfies:

$$Vo 3 + Vo 2 - 2 Vo 1 = ( ( Vsig 2 - Vbr 3 ) + ( Vsig 2 - Vbr 6 ) ) + ( ( Vsig 1 + Vbr 2 ) + ( Vsig 1 + Vbr 5 ) ) - 2 ( ( Vsig 2 - Vbr 4 ) + ( Vsig 1 - Vbr 1 ) ) = 4 Vbr 1 = Vref$$

FIG. 15 shows an eleventh example of the present application. The differences between the eleventh example and the sixth example shown in FIG. 10 and the seventh example shown in FIG. 11 will be explained below, while similar aspects will not be repeated.

The magnetic field sensing device comprises a second magnetic field generating unit 21.

The second magnetic field generating unit 21 is configured to apply a predetermined second excitation magnetic field Br2 to the second sensing unit 20. The direction and magnetic field intensity of the second excitation magnetic field Br2 are predetermined and known.

The second magnetic field generating unit 21 may be configured as structures such as a coil, magnet, or other structures capable of generating local magnetic fields to apply the second excitation magnetic field Br2.

The second magnetic field generating unit 21 may be arranged close to the second sensing unit 20 to apply the second excitation magnetic field Br2 to the second sensing unit 20.

Correspondingly, the ambient magnetic field sensed by the second sensing unit 20 includes the second excitation magnetic field Br2.

In a specific example, the second excitation magnetic field Br2 has a same direction as the first excitation magnetic field Br1. Specifically, the second excitation magnetic field Br2 has a same direction and equal intensity as the first excitation magnetic field Br1.

The second magnetic field generating unit 21 may be configured as shown in the second example in FIG. 6.

The magnetic field sensing device comprises a third magnetic field generating unit 31.

The third magnetic field generating unit 31 is configured to apply a predetermined third excitation magnetic field Br3 to the third sensing unit 30. The direction and magnetic field intensity of the third excitation magnetic field Br3 are predetermined and known.

The third magnetic field generating unit 31 may be configured as structures such as a coil, magnet, or other structures capable of generating local magnetic fields to apply the third excitation magnetic field Br3.

The third magnetic field generating unit 31 may be arranged close to the third sensing unit 30 to apply the third excitation magnetic field Br3 to the third sensing unit 30.

Correspondingly, the ambient magnetic field sensed by the third sensing unit 30 includes the third excitation magnetic field Br3.

In a specific example, the third excitation magnetic field Br3 has a same direction as the second excitation magnetic field Br2. Specifically, the third excitation magnetic field Br3 has a same direction and equal intensity as the second excitation magnetic field Br2.

In a specific example, the third excitation magnetic field Br3 has a same direction as the first excitation magnetic field Br1. Specifically, the third excitation magnetic field Br3 has a same direction and equal intensity as the first excitation magnetic field Br1.

The third magnetic field generating unit 31 may be configured as shown in the third example in FIG. 7.

The magnetic field sensing device comprises a fifth magnetic field generating unit 51.

The fifth magnetic field generating unit 51 is configured to apply a predetermined fifth excitation magnetic field Br5 to the fifth sensing unit 50. The direction and magnetic field intensity of the fifth excitation magnetic field Br5 are predetermined and known.

The fifth magnetic field generating unit 51 may be configured as structures such as a coil, magnet, or other structures capable of generating local magnetic fields to apply the fifth excitation magnetic field Br5.

The fifth magnetic field generating unit 51 may be arranged close to the fifth sensing unit 50 to apply the fifth excitation magnetic field Br5 to the fifth sensing unit 50.

Correspondingly, the ambient magnetic field sensed by the fifth sensing unit 50 includes the fifth excitation magnetic field Br5.

In a specific example, the fifth excitation magnetic field Br5 has a same direction as the second excitation magnetic field Br2. Specifically, the fifth excitation magnetic field Br5 has a same magnetic field intensity as the second excitation magnetic field Br2.

In a specific example, the fifth excitation magnetic field Br5 has a same direction as the first excitation magnetic field Br1. Specifically, the fifth excitation magnetic field Br5 has a same magnetic field intensity as the first excitation magnetic field Br1.

The fifth magnetic field generating unit 51 may be configured as shown in the eighth example in FIG. 12.

The magnetic field sensing device comprises a sixth magnetic field generating unit 61.

The sixth magnetic field generating unit 61 is configured to apply a predetermined sixth excitation magnetic field Br6 to the sixth sensing unit 60. The direction and magnetic field intensity of the sixth excitation magnetic field Br6 are predetermined and known.

The sixth magnetic field generating unit 61 may be configured as structures such as a coil, magnet, or other structures capable of generating local magnetic fields to apply the sixth excitation magnetic field Br6.

The sixth magnetic field generating unit 61 may be arranged close to the sixth sensing unit 60 to apply the sixth excitation magnetic field Br6 to the sixth sensing unit 60.

Correspondingly, the ambient magnetic field sensed by the sixth sensing unit 60 includes the sixth excitation magnetic field Br6.

In a specific example, the sixth excitation magnetic field Br6 has a same direction as the third excitation magnetic field Br3. Specifically, the sixth excitation magnetic field Br6 has a same magnetic field intensity as the third excitation magnetic field Br3.

In a specific example, the sixth excitation magnetic field Br6 has a same direction as the first excitation magnetic field Br1. Specifically, the sixth excitation magnetic field Br6 has a same magnetic field intensity as the first excitation magnetic field Br1.

The sixth magnetic field generating unit 61 may be configured as shown in the eighth example in FIG. 12.

In combination with FIG. 1, the operation unit 800 is configured to determine a magnetic field sensing signal of the magnetic field sensing device based on a value of the second sensing signal and a value of the fifth sensing signal; the operation unit 800 is configured to determine a magnetic field sensing signal of the magnetic field sensing device based on a value of the third sensing signal and a value of the sixth sensing signal.

In a specific example, the operation unit 800 is configured to determine a magnetic field sensing signal of the magnetic field sensing device based on a sum of the value of the second sensing signal and the value of the fifth sensing signal, and a sum of the value of the third sensing signal and the value of the sixth sensing signal.

The magnetic field sensing signal includes a differential sensing signal corresponding to the first region S1 and the second region S2.

For example, when the first direction X is defined as the positive direction and Vbr3+Vbr6=Vbr2+Vbr5, the value of the differential sensing signal Vdiff satisfies:

$$Vo 3 - Vo 2 = ( ( Vsig 2 - Vbr 3 ) + ( Vsig 2 - Vbr 6 ) ) - ( ( Vsig 1 - Vbr 2 ) + ( Vsig 1 - Vbr 5 ) ) = 2 ( Vsig 2 - Vsig 1 ) = Vdiff$$

Preferably, Vbr2=Vbr3=Vbr5=Vbr6.

The magnetic field sensing device comprises a fourth magnetic field generating unit 41.

The fourth magnetic field generating unit 41 is configured to apply a predetermined fourth excitation magnetic field Br4 to the fourth sensing unit 40. The direction and magnetic field intensity of the fourth excitation magnetic field Br4 are predetermined and known.

The fourth magnetic field generating unit 41 may be configured as structures such as a coil, magnet, or other structures capable of generating local magnetic fields to apply the fourth excitation magnetic field Br4.

The fourth magnetic field generating unit 41 may be arranged close to the fourth sensing unit 40 to apply the fourth excitation magnetic field Br4 to the fourth sensing unit 40.

Correspondingly, the ambient magnetic field sensed by the fourth sensing unit 40 includes the fourth excitation magnetic field Br4.

In a specific example, the fourth excitation magnetic field Br4 has a direction opposite to the first excitation magnetic field Br1. Specifically, the fourth excitation magnetic field Br4 has a direction opposite to and equal intensity as the first excitation magnetic field Br1.

The fourth magnetic field generating unit 41 may be configured as shown in the sixth example in FIG. 10 and the seventh example in FIG. 11.

In combination with FIG. 1, the operation unit 800 is configured to determine a magnetic field sensing signal of the magnetic field sensing device based on a value of the second sensing signal and a value of the fifth sensing signal; the operation unit 800 is configured to determine a magnetic field sensing signal of the magnetic field sensing device based on a value of the first sensing signal and a value of the fourth sensing signal.

In a specific example, the operation unit 800 is configured to determine a magnetic field sensing signal of the magnetic field sensing device based on a sum of the value of the second sensing signal and the value of the fifth sensing signal, and a difference between the value of the first sensing signal and the value of the fourth sensing signal.

The magnetic field sensing signal includes a common-mode sensing signal corresponding to the first region S1 and the second region S2.

For example, when the first direction X is defined as the positive direction and Vbr2+Vbr5=Vbr4+Vbr1, the value of the common-mode sensing signal Vcom satisfies:

$$Vo 2 - Vo 1 = ( ( Vsig 1 - Vbr 2 ) + ( Vsig 1 - Vbr 5 ) ) - ( ( Vsig 1 - Vbr 1 ) - ( Vsig 2 + Vbr 4 ) ) = Vsig 1 + Vsig 2 = Vcom$$

In combination with FIG. 1, the operation unit 800 is configured to determine the calibration signal based on a value of the second sensing signal and a value of the fifth sensing signal; the operation unit 800 is configured to determine the calibration signal based on a value of the third sensing signal and a value of the sixth sensing signal; the operation unit 800 is configured to determine the calibration signal based on a value of the first sensing signal and a value of the fourth sensing signal.

In a specific example, the operation unit 800 is configured to determine the calibration signal based on a sum of the value of the second sensing signal and the value of the fifth sensing signal, a sum of the value of the third sensing signal and the value of the sixth sensing signal, and a difference between the value of the first sensing signal and the value of the fourth sensing signal.

For example, when the first direction X is defined as the positive direction and Vbr1=Vbr2=Vbr3=Vbr4=Vbr5=Vbr6, the calibration signal Vref satisfies:

$$Vo 3 - Vo 2 + 2 Vo 1 = ( ( Vsig 2 - Vbr 3 ) + ( Vsig 2 - Vbr 6 ) ) - ( ( Vsig 1 - Vbr 2 ) + ( Vsig 1 - Vbr 5 ) ) + 2 ( ( Vsig 1 - Vbr 1 ) - ( Vsig 2 + Vbr 4 ) ) = - 4 Vbr 1 = Vref$$

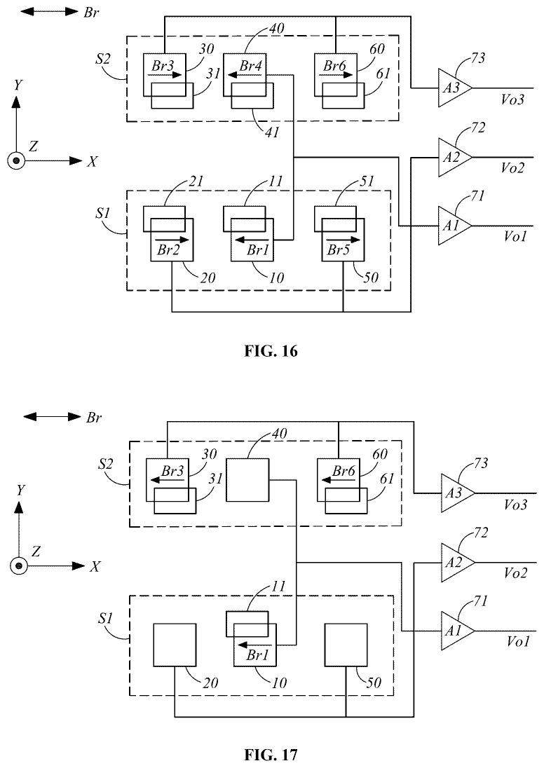

FIG. 16 shows a twelfth example of the present application. The differences between the twelfth example and the eleventh example shown in FIG. 15 will be explained below, while similar aspects will not be repeated.

In the twelfth example, the second excitation magnetic field Br2 has a direction opposite to the first excitation magnetic field Br1. Specifically, the second excitation magnetic field Br2 has a direction opposite to and equal intensity as the first excitation magnetic field Br1.

The third excitation magnetic field Br3 has a same direction and equal intensity as the second excitation magnetic field Br2. The third excitation magnetic field Br3 has a direction opposite to and equal intensity as the first excitation magnetic field.

The fifth excitation magnetic field Br5 has a same direction and equal intensity as the second excitation magnetic field Br2. The fifth excitation magnetic field Br5 has a direction opposite to and equal intensity as the first excitation magnetic field.

The sixth excitation magnetic field Br6 has a same direction and equal intensity as the second excitation magnetic field Br2. The sixth excitation magnetic field Br6 has a direction opposite to and equal intensity as the first excitation magnetic field.

The fourth excitation magnetic field Br4 has a same direction as the first excitation magnetic field Br1. Specifically, the fourth excitation magnetic field Br4 has a same direction and equal intensity as the first excitation magnetic field Br1.

In combination with FIG. 1, the operation unit 800 is configured to determine a magnetic field sensing signal of the magnetic field sensing device based on a value of the second sensing signal and a value of the fifth sensing signal; the operation unit 800 is configured to determine a magnetic field sensing signal of the magnetic field sensing device based on a value of the third sensing signal and a value of the sixth sensing signal; the operation unit 800 is configured to determine a magnetic field sensing signal of the magnetic field sensing device based on a value of the first sensing signal and a value of the fourth sensing signal.

In a specific example, the operation unit 800 is configured to determine a magnetic field sensing signal of the magnetic field sensing device based on a sum of the value of the second sensing signal and the value of the fifth sensing signal, a sum of the value of the third sensing signal and the value of the sixth sensing signal, and a sum of the value of the first sensing signal and the value of the fourth sensing signal.

The magnetic field sensing signal includes a common-mode sensing signal corresponding to the first region S1 and the second region S2.

For example, when the first direction X is defined as the positive direction and Vbr3+Vbr6+Vbr2+Vbr5=2(Vbr1+Vbr4), the value of the common-mode sensing signal Vcom satisfies:

$$Vo 3 + Vo 2 + 2 Vo 1 = ( ( Vsig 2 + Vbr 3 ) + ( Vsig 2 + Vbr 6 ) ) + ( ( Vsig 1 + Vbr 2 ) + ( Vsig 1 + Vbr 5 ) ) + 2 ( ( Vsig 1 - Vbr 1 ) + ( Vsig 2 - Vbr 4 ) ) = 4 ( Vsig 2 + Vsig 1 ) = Vcom$$

In combination with FIG. 1, the operation unit 800 is configured to determine the calibration signal based on a value of the second sensing signal and a value of the fifth sensing signal; the operation unit 800 is configured to determine the calibration signal based on a value of the third sensing signal and a value of the sixth sensing signal; the operation unit 800 is configured to determine the calibration signal based on a value of the first sensing signal and a value of the fourth sensing signal.

In a specific example, the operation unit 800 is configured to determine the calibration signal based on a sum of the value of the second sensing signal and the value of the fifth sensing signal, a sum of the value of the third sensing signal and the value of the sixth sensing signal, and a sum of the value of the first sensing signal and the value of the fourth sensing signal.

For example, when the first direction X is defined as the positive direction and Vbr1=Vbr2=Vbr3=Vbr4=Vbr5=Vbr6, the calibration signal Vref satisfies:

$$Vo 3 + Vo 2 - 2 Vo 1 = ( ( Vsig 2 + Vbr 3 ) + ( Vsig 2 + Vbr 6 ) ) + ( ( Vsig 1 + Vbr 2 ) + ( Vsig 1 + Vbr 5 ) ) - 2 ( ( Vsig 1 - Vbr 1 ) - ( Vsig 2 - Vbr 4 ) ) = 8 Vbr = Vref$$

FIG. 17 shows a thirteenth example of the present application. The differences between the thirteenth example and the sixth example shown in FIG. 10 and the seventh example shown in FIG. 11 will be explained below, while similar aspects will not be repeated.

The magnetic field sensing device comprises a third magnetic field generating unit 31.

The third magnetic field generating unit 31 is configured to apply a predetermined third excitation magnetic field Br3 to the third sensing unit 30. The direction and magnetic field intensity of the third excitation magnetic field Br3 are predetermined and known.

The third magnetic field generating unit 31 may be configured as structures such as a coil, magnet, or other structures capable of generating local magnetic fields to apply the third excitation magnetic field Br3.

The third magnetic field generating unit 31 may be arranged close to the third sensing unit 30 to apply the third excitation magnetic field Br3 to the third sensing unit 30.

Correspondingly, the ambient magnetic field sensed by the third sensing unit 30 includes the third excitation magnetic field Br3.

In a specific example, the third excitation magnetic field Br3 has a same direction as the first excitation magnetic field Br1. Specifically, the third excitation magnetic field Br3 has a same direction and equal intensity as the first excitation magnetic field Br1.

The third magnetic field generating unit 31 may be configured as shown in the third example in FIG. 7.

The magnetic field sensing device comprises a sixth magnetic field generating unit 61.

The sixth magnetic field generating unit 61 is configured to apply a predetermined sixth excitation magnetic field Br6 to the sixth sensing unit 60. The direction and magnetic field intensity of the sixth excitation magnetic field Br6 are predetermined and known.

The sixth magnetic field generating unit 61 may be configured as structures such as a coil, magnet, or other structures capable of generating local magnetic fields to apply the sixth excitation magnetic field Br6.

The sixth magnetic field generating unit 61 may be arranged close to the sixth sensing unit 60 to apply the sixth excitation magnetic field Br6 to the sixth sensing unit 60.

Correspondingly, the ambient magnetic field sensed by the sixth sensing unit 60 includes the sixth excitation magnetic field Br6.

In a specific example, the sixth excitation magnetic field Br6 has a same direction as the third excitation magnetic field Br3. Specifically, the sixth excitation magnetic field Br6 has a same magnetic field intensity as the third excitation magnetic field Br3.

In a specific example, the sixth excitation magnetic field Br6 has a same direction as the first excitation magnetic field Br1. Specifically, the sixth excitation magnetic field Br6 has a same magnetic field intensity as the first excitation magnetic field Br1.

The sixth magnetic field generating unit 61 may be configured as shown in the eighth example in FIG. 12.

In combination with FIG. 1, the operation unit 800 is configured to determine a magnetic field sensing signal of the magnetic field sensing device based on a value of the second sensing signal and a value of the fifth sensing signal; the operation unit 800 is configured to determine the magnetic field sensing signal of the magnetic field sensing device based on a value of the third sensing signal and a value of the sixth sensing signal; the operation unit 800 is configured to determine the magnetic field sensing signal of the magnetic field sensing device based on a value of the first sensing signal and a value of the fourth sensing signal.

In a specific example, the operation unit 800 is configured to determine a magnetic field sensing signal of the magnetic field sensing device based on a sum of the value of the second sensing signal and the value of the fifth sensing signal, a sum of the value of the third sensing signal and the value of the sixth sensing signal, and a difference between the value of the first sensing signal and the value of the fourth sensing signal.

The magnetic field sensing signal includes a differential sensing signal corresponding to the first region S1 and the second region S2.

For example, when the first direction X is defined as the positive direction and Vbr3+Vbr6=2Vbr1, the value Vdiff of the differential sensing signal satisfies:

$$Vo 3 - Vo 2 - 0.5 * ( Vo 3 - Vo 2 + 2 Vo 1 ) = ( ( Vsig 2 - Vbr 3 ) + ( Vsig 2 - Vbr 6 ) ) - ( Vsig 1 + Vsig 1 ) - 0.5 * ( ( ( Vsig 2 - Vbr 3 ) + ( Vsig 2 - Vbr 6 ) ) - ( Vsig 1 + Vsig 1 ) + 2 ( ( Vsig 1 - Vbr 1 ) - Vsig 2 ) ) = 2 ( Vsig 2 - Vsig 1 ) = Vdiff$$

Preferably, Vbr1=Vbr3=Vbr6.

The magnetic field sensing signal includes a common-mode sensing signal corresponding to the first region S1 and the second region S2.

For example, when the first direction X is defined as the positive direction and Vbr3+Vbr6=2Vbr1, the value Vcom of the common-mode sensing signal satisfies:

$$Vo 3 + Vo 2 - 0.5 * ( Vo 3 - Vo 2 + 2 Vo 1 ) = ( ( Vsig 2 - Vbr 3 ) + ( Vsig 2 - Vbr 6 ) ) + ( Vsig 1 + Vsig 1 ) - 0.5 * ( ( ( Vsig 2 - Vbr 3 ) + ( Vsig 2 - Vbr 6 ) ) - ( Vsig 1 + Vsig 1 ) + 2 ( ( Vsig 1 - Vbr 1 ) - Vsig 2 ) ) = 2 ( Vsig 2 + Vsig 1 ) = Vcom$$

Preferably, Vbr1=Vbr3=Vbr6.

In combination with FIG. 1, the operation unit 800 is configured to determine a calibration signal based on a value of the second sensing signal and a value of the fifth sensing signal; the operation unit 800 is configured to determine the calibration signal based on a value of the third sensing signal and a value of the sixth sensing signal; the operation unit 800 is configured to determine the calibration signal based on a value of the first sensing signal and a value of the fourth sensing signal.

In a specific example, the operation unit 800 is configured to determine the calibration signal based on a sum of the value of the second sensing signal and the value of the fifth sensing signal, a sum of the value of the third sensing signal and the value of the sixth sensing signal, and a difference between the value of the first sensing signal and the value of the fourth sensing signal.

For example, when the first direction X is defined as the positive direction and Vbr1=Vbr3=Vbr6, the calibration signal Vref satisfies:

$$Vo 3 - Vo 2 + 2 Vo 1 = ( ( Vsig 2 - Vbr 3 ) + ( Vsig 2 - Vbr 6 ) ) - ( Vsig 1 + Vsig 1 ) + 2 ( ( Vsig 1 - Vbr 1 ) - Vsig 2 ) = - 4 Vbr 1 = Vref$$

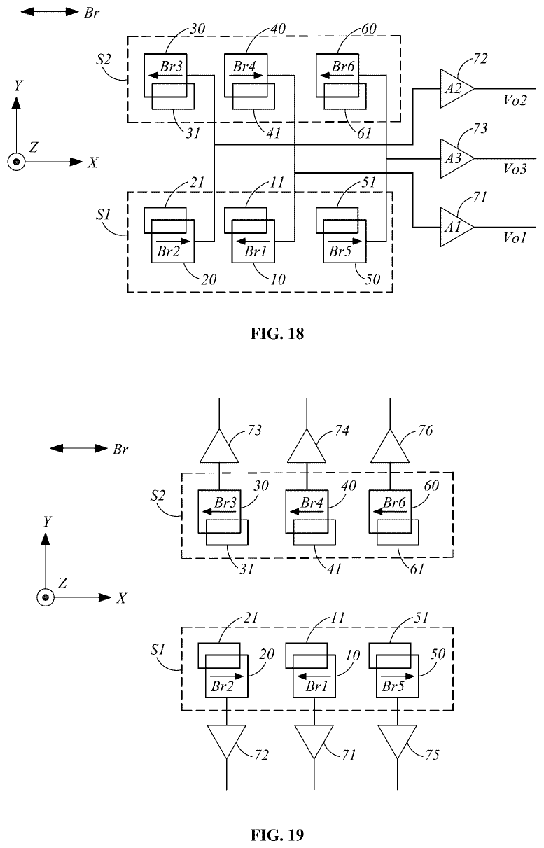

FIG. 18 shows a fourteenth example of the present application. The differences between the fourteenth example and the fifth example shown in FIG. 9 will be explained below, while similar aspects will not be repeated.

The magnetic field sensing device comprises a second magnetic field generating unit 21.

The second magnetic field generating unit 21 is configured to apply a predetermined second excitation magnetic field Br2 to the second sensing unit 20. The direction and magnetic field intensity of the second excitation magnetic field Br2 are predetermined and known.

The second magnetic field generating unit 21 may be configured as structures such as a coil, magnet, or other structures capable of generating local magnetic fields to apply the second excitation magnetic field Br2.

The second magnetic field generating unit 21 may be arranged close to the second sensing unit 20 to apply the second excitation magnetic field Br2 to the second sensing unit 20.

Correspondingly, the ambient magnetic field sensed by the second sensing unit 20 includes the second excitation magnetic field Br2.

In a specific example, the second excitation magnetic field Br2 has a direction opposite to the first excitation magnetic field Br1. Specifically, the second excitation magnetic field Br2 has a direction opposite to and equal intensity as the first excitation magnetic field Br1.

The second magnetic field generating unit 21 may be configured as shown in the second example in FIG. 6.

The magnetic field sensing device comprises a third magnetic field generating unit 31.

The third magnetic field generating unit 31 is configured to apply a predetermined third excitation magnetic field Br3 to the third sensing unit 30. The direction and magnetic field intensity of the third excitation magnetic field Br3 are predetermined and known.

The third magnetic field generating unit 31 may be configured as structures such as a coil, magnet, or other structures capable of generating local magnetic fields to apply the third excitation magnetic field Br3.

The third magnetic field generating unit 31 may be arranged close to the third sensing unit 30 to apply the third excitation magnetic field Br3 to the third sensing unit 30.

Correspondingly, the ambient magnetic field sensed by the third sensing unit 30 includes the third excitation magnetic field Br3.

In a specific example, the third excitation magnetic field Br3 has a direction opposite to the second excitation magnetic field Br2. Specifically, the third excitation magnetic field Br3 has a direction opposite to and equal intensity as the second excitation magnetic field Br2.

In a specific example, the third excitation magnetic field Br3 has a same direction as the first excitation magnetic field Br1. Specifically, the third excitation magnetic field Br3 has a same direction and equal intensity as the first excitation magnetic field Br1.

The third magnetic field generating unit 31 may be configured as shown in the third example in FIG. 7.

In a specific example, the magnetic field sensing device comprises a second amplifier 72. An input terminal of the second amplifier 72 is coupled to the second sensing unit 20 and the third sensing unit 30, and an output terminal of the second amplifier 72 is configured to generate a second intermediate output.

The magnetic field sensing device comprises a fifth sensing unit 50.

The fifth sensing unit 50 is arranged in the first region S1.

The fifth sensing unit 50 is configured to sense an ambient magnetic field to generate a fifth sensing signal.

The ambient magnetic field sensed by the fifth sensing unit 50 includes either the overall ambient magnetic field of the environment where the magnetic field sensing device is located, or the magnetic field component of the overall ambient magnetic field at the first region S1.

The fifth sensing unit 50 may be configured as shown in the sixth example in FIG. 10.

The magnetic field sensing device comprises a sixth sensing unit 60.

The sixth sensing unit 60 is arranged in the second region S2.

The sixth sensing unit 60 is configured to sense an ambient magnetic field to generate a sixth sensing signal.

The ambient magnetic field sensed by the sixth sensing unit 60 includes either the overall ambient magnetic field of the environment where the magnetic field sensing device is located, or the magnetic field component of the overall ambient magnetic field at the second region S2.

The sixth sensing unit 60 may be configured as shown in the sixth example in FIG. 10.

The magnetic field sensing device comprises a fifth magnetic field generating unit 51.

The fifth magnetic field generating unit 51 is configured to apply a predetermined fifth excitation magnetic field Br5 to the fifth sensing unit 50. The direction and magnetic field intensity of the fifth excitation magnetic field Br5 are predetermined and known.

The fifth magnetic field generating unit 51 may be configured as structures such as a coil, magnet, or other structures capable of generating local magnetic fields to apply the fifth excitation magnetic field Br5.

The fifth magnetic field generating unit 51 may be arranged close to the fifth sensing unit 50 to apply the fifth excitation magnetic field Br5 to the fifth sensing unit 50.

Correspondingly, the ambient magnetic field sensed by the fifth sensing unit 50 includes the fifth excitation magnetic field Br5.

In a specific example, the fifth excitation magnetic field Br5 has a same direction as the second excitation magnetic field Br2. Specifically, the fifth excitation magnetic field Br5 has a same magnetic field intensity as the second excitation magnetic field Br2.

In a specific example, the fifth excitation magnetic field Br5 has a direction opposite to the first excitation magnetic field Br1. Specifically, the fifth excitation magnetic field Br5 has a same magnetic field intensity as the first excitation magnetic field Br1.

The fifth magnetic field generating unit 51 may be configured as shown in the eighth example in FIG. 12.

The magnetic field sensing device comprises a sixth magnetic field generating unit 61.

The sixth magnetic field generating unit 61 is configured to apply a predetermined sixth excitation magnetic field Br6 to the sixth sensing unit 60. The direction and magnetic field intensity of the sixth excitation magnetic field Br6 are predetermined and known.

The sixth magnetic field generating unit 61 may be configured as structures such as a coil, magnet, or other structures capable of generating local magnetic fields to apply the sixth excitation magnetic field Br6.

The sixth magnetic field generating unit 61 may be arranged close to the sixth sensing unit 60 to apply the sixth excitation magnetic field Br6 to the sixth sensing unit 60.

Correspondingly, the ambient magnetic field sensed by the sixth sensing unit 60 includes the sixth excitation magnetic field Br6.

In a specific example, the sixth excitation magnetic field Br6 has a same direction as the third excitation magnetic field Br3. Specifically, the sixth excitation magnetic field Br6 has a same magnetic field intensity as the third excitation magnetic field Br3.

In a specific example, the sixth excitation magnetic field Br6 has a same direction as the first excitation magnetic field Br1. Specifically, the sixth excitation magnetic field Br6 has a same magnetic field intensity as the first excitation magnetic field Br1.

The sixth magnetic field generating unit 61 may be configured as shown in the eighth example in FIG. 12.

In a specific example, the magnetic field sensing device comprises a third amplifier 73. An input terminal of the third amplifier 73 is coupled to the fifth sensing unit 50 and the sixth sensing unit 60, and an output terminal of the third amplifier 73 is configured to generate a third intermediate output.

In a specific example, the magnetic field sensing device comprises a first amplifier 71. An input terminal of the first amplifier 71 is coupled to the first sensing unit 10 and the fourth sensing unit 40, and an output terminal of the first amplifier 71 is configured to generate a first intermediate output.

In combination with FIG. 1, the operation unit 800 is configured to determine the magnetic field sensing signal of the magnetic field sensing device based on a difference between the value of the third sensing signal and the value of the second sensing signal; the operation unit 800 is configured to determine the magnetic field sensing signal of the magnetic field sensing device based on a difference between the value of the sixth sensing signal and the value of the fifth sensing signal; the operation unit 800 is configured to determine the magnetic field sensing signal of the magnetic field sensing device based on a difference between the value of the first sensing signal and the value of the fourth sensing signal.

In a specific example, the operation unit 800 is configured to determine the magnetic field sensing signal of the magnetic field sensing device based on a difference between the value of the third sensing signal and the value of the second sensing signal, a difference between the value of the sixth sensing signal and the value of the fifth sensing signal, and a difference between the value of the first sensing signal and the value of the fourth sensing signal.

The magnetic field sensing signal includes a differential sensing signal corresponding to the first region S1 and the second region S2.

For example, when the first direction X is defined as the positive direction and Vbr3+Vbr2+Vbr6+Vbr5=4Vbr1, the value Vdiff of the differential sensing signal satisfies:

$$Vo 2 + Vo 3 - 4 Vo 1 = ( ( Vsig 2 - Vbr 3 ) - ( Vsig 1 + Vbr 2 ) ) + ( ( Vsig 2 - Vbr 6 ) - ( Vsig 1 + Vbr 5 ) ) - 4 ( ( Vsig 1 - Vbr 1 ) - Vsig 2 ) = 6 ( Vsig 2 - Vsig 1 ) = Vdiff$$

Preferably, Vbr1=Vbr2=Vbr3=Vbr5=Vbr6.

In combination with FIG. 1, the operation unit 800 is configured to determine the calibration signal based on a value of the third sensing signal and a value of the second sensing signal; the operation unit 800 is configured to determine the calibration signal based on a value of the sixth sensing signal and a value of the fifth sensing signal; the operation unit 800 is configured to determine the calibration signal based on a value of the first sensing signal and a value of the fourth sensing signal.

In a specific example, the operation unit 800 is configured to determine the calibration signal based on a difference between the value of the third sensing signal and the value of the second sensing signal, a difference between the value of the sixth sensing signal and the value of the fifth sensing signal, and a difference between the value of the first sensing signal and the value of the fourth sensing signal.

For example, when the first direction X is defined as the positive direction and Vbr1=Vbr2=Vbr3=Vbr5=Vbr6, the value Vref of the calibration signal satisfies:

$$Vo 2 + Vo 3 + 2 Vo 1 = ( ( Vsig 2 - Vbr 3 ) - ( Vsig 1 + Vbr 2 ) ) + ( ( Vsig 2 - Vbr 6 ) - ( Vsig 1 + Vbr 5 ) ) + 2 ( ( Vsig 1 - Vbr 1 ) - Vsig 2 ) = - 6 Vbr 1 = Vref$$

In a specific example, the magnetic field sensing device comprises a fourth magnetic field generating unit 41.

The fourth magnetic field generating unit 41 is configured to apply a predetermined fourth excitation magnetic field Br4 to the fourth sensing unit 40. The direction and magnetic field intensity of the fourth excitation magnetic field Br4 are predetermined and known.

The fourth magnetic field generating unit 41 may be configured as structures such as a coil, magnet, or other structures capable of generating local magnetic fields to apply the fourth excitation magnetic field Br4.

The fourth magnetic field generating unit 41 may be arranged close to the fourth sensing unit 40 to apply the fourth excitation magnetic field Br4 to the fourth sensing unit 40.

Correspondingly, the ambient magnetic field sensed by the fourth sensing unit 40 includes the fourth excitation magnetic field Br4.

In a specific example, the fourth excitation magnetic field Br4 has a direction opposite to the first excitation magnetic field Br1. Specifically, the fourth excitation magnetic field Br4 has a direction opposite to and equal intensity as the first excitation magnetic field Br1.

The fourth magnetic field generating unit 41 may be configured as shown in the sixth example in FIG. 10 and the seventh example in FIG. 11.

In the example, the magnetic field sensing signal includes a differential sensing signal corresponding to the first region S1 and the second region S2.

For example, when the first direction X is defined as the positive direction and Vbr3+Vbr2+Vbr6+Vbr5=2(Vbr1+Vbr4), the value Vdiff of the differential sensing signal satisfies:

$$Vo 2 + Vo 3 - 2 Vo 1 = ( ( Vsig 2 - Vbr 3 ) - ( Vsig 1 + Vbr 2 ) ) + ( ( Vsig 2 - Vbr 6 ) - ( Vsig 1 + Vbr 5 ) ) - 2 ( ( Vsig 1 - Vbr 1 ) - ( Vsig 2 + Vbr 4 ) ) = 4 ( Vsig 2 - Vsig 1 ) = Vdiff$$

Preferably, Vbr1=Vbr2=Vbr3=Vbr4=Vbr5=Vbr6.

For the calibration signal, for example, when the first direction X is defined as the positive direction and Vbr1=Vbr2=Vbr3=Vbr4=Vbr5=Vbr6, the value Vref of the calibration signal satisfies:

$$Vo 2 + Vo 3 + 2 Vo 1 = ( ( Vsig 2 - Vbr 3 ) - ( Vsig 1 + Vbr 2 ) ) + ( ( Vsig 2 - Vbr 6 ) - ( Vsig 1 + Vbr 5 ) ) + 2 ( ( Vsig 1 - Vbr 1 ) - ( Vsig 2 + Vbr 4 ) ) = - 8 Vbr 1 = Vref$$

FIG. 19 shows a fifteenth example of the present application. The differences between the fifteenth example and the fourteenth example shown in FIG. 18 will be explained below, while similar aspects will not be repeated.

The magnetic field sensing device comprises a first amplifier 71. An input terminal of the first amplifier 71 is coupled to the first sensing unit 10, and an output terminal of the first amplifier 71 is configured to generate a first sensing signal.

The magnetic field sensing device comprises a second amplifier 72. An input terminal of the second amplifier 72 is coupled to the second sensing unit 20, and an output terminal of the second amplifier 72 is configured to generate a second sensing signal.

The magnetic field sensing device comprises a third amplifier 73. An input terminal of the third amplifier 73 is coupled to the third sensing unit 30, and an output terminal of the third amplifier 73 is configured to generate a third sensing signal.

The magnetic field sensing device comprises a fourth amplifier 74. An input terminal of the fourth amplifier 74 is coupled to the fourth sensing unit 40, and an output terminal of the fourth amplifier 74 is configured to generate a fourth sensing signal.

The magnetic field sensing device comprises a fifth amplifier 75. An input terminal of the fifth amplifier 75 is coupled to the fifth sensing unit 50, and an output terminal of the fifth amplifier 75 is configured to generate a fifth sensing signal.

The magnetic field sensing device comprises a sixth amplifier 76. An input terminal of the sixth amplifier 76 is coupled to the sixth sensing unit 60, and an output terminal of the sixth amplifier 76 is configured to generate a sixth sensing signal.

The magnetic field sensing device comprises a fourth magnetic field generating unit 41.

The fourth magnetic field generating unit 41 is configured to apply a predetermined fourth excitation magnetic field Br4 to the fourth sensing unit 40. The direction and magnetic field intensity of the fourth excitation magnetic field Br4 are predetermined and known.

The fourth magnetic field generating unit 41 may be configured as structures such as a coil, magnet, or other structures capable of generating local magnetic fields to apply the fourth excitation magnetic field Br4.

The fourth magnetic field generating unit 41 may be arranged close to the fourth sensing unit 40 to apply the fourth excitation magnetic field Br4 to the fourth sensing unit 40.

Correspondingly, the ambient magnetic field sensed by the fourth sensing unit 40 includes the fourth excitation magnetic field Br4.

In a specific example, the fourth excitation magnetic field Br4 has a direction opposite to the first excitation magnetic field Br1. Specifically, the fourth excitation magnetic field Br4 has a direction opposite to and equal intensity as the first excitation magnetic field Br1.

In a specific example, the fourth excitation magnetic field Br4 has a same direction as the first excitation magnetic field Br1. Specifically, the fourth excitation magnetic field Br4 has a same direction and equal intensity as the first excitation magnetic field Br1.

The fourth magnetic field generating unit 41 may be configured as shown in the sixth example in FIG. 10 and the seventh example in FIG. 11.

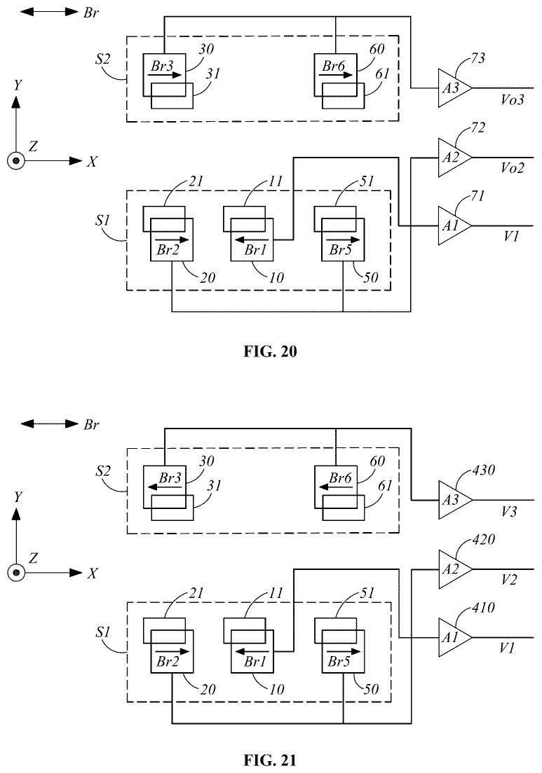

FIG. 20 shows a sixteenth example of the present application. The differences between the sixteenth example and the first example shown in FIG. 5 will be explained below, while similar aspects will not be repeated.

The magnetic field sensing device comprises a fifth sensing unit 50.

The fifth sensing unit 50 is arranged in the first region S1.

The fifth sensing unit 50 is configured to sense an ambient magnetic field to generate a fifth sensing signal.

The ambient magnetic field sensed by the fifth sensing unit 50 includes either the overall ambient magnetic field of the environment where the magnetic field sensing device is located, or the magnetic field component of the overall ambient magnetic field at the first region S1.

The fifth sensing unit 50 may be configured as shown in the sixth example in FIG. 10.

The magnetic field sensing device comprises a sixth sensing unit 60.

The sixth sensing unit 60 is arranged in the second region S2.

The sixth sensing unit 60 is configured to sense an ambient magnetic field to generate a sixth sensing signal.

The ambient magnetic field sensed by the sixth sensing unit 60 includes either the overall ambient magnetic field of the environment where the magnetic field sensing device is located, or the magnetic field component of the overall ambient magnetic field at the second region S2.

The sixth sensing unit 60 may be configured as shown in the sixth example in FIG. 10.

In a specific example, the magnetic field sensing device comprises a first amplifier 71. An input terminal of the first amplifier 71 is coupled to the first sensing unit 10, and an output terminal of the first amplifier 71 is configured to generate a first sensing signal.

In a specific example, the magnetic field sensing device comprises a second amplifier 72. An input terminal of the second amplifier 72 is coupled to the second sensing unit 20 and the fifth sensing unit 50, and an output terminal of the second amplifier 72 is configured to generate a second intermediate output.

In a specific example, the magnetic field sensing device comprises a third amplifier 73. An input terminal of the third amplifier 73 is coupled to the third sensing unit 30 and the sixth sensing unit 60, and an output terminal of the third amplifier 73 is configured to generate a third intermediate output.

In combination with FIG. 1, the operation unit 800 is configured to determine the magnetic field sensing signal of the magnetic field sensing device based on a value of the second sensing signal and a value of the fifth sensing signal; the operation unit 800 is configured to determine the magnetic field sensing signal of the magnetic field sensing device based on a value of the third sensing signal and a value of the sixth sensing signal.

In a specific example, the operation unit 800 is configured to determine the magnetic field sensing signal of the magnetic field sensing device based on a sum of the value of the second sensing signal and the value of the fifth sensing signal and a sum of the value of the third sensing signal and the value of the sixth sensing signal.

The magnetic field sensing signal includes a differential sensing signal corresponding to the first region S1 and the second region S2.

For example, when the first direction X is defined as the positive direction, the value Vdiff of the differential sensing signal satisfies:

$$Vo 3 - Vo 2 = ( Vsig 2 + Vsig 2 ) - ( Vsig 1 + Vsig 1 ) = 2 ( Vsig 2 - Vsig 1 ) = Vdiff$$

The magnetic field sensing signal includes a common-mode sensing signal corresponding to the first region S1 and the second region S2.

For example, when the first direction X is defined as the positive direction, the value Vcom of the common-mode sensing signal satisfies:

$$Vo 3 + Vo 2 = ( Vsig 2 + Vsig 2 ) + ( Vsig 1 + Vsig 1 ) = 2 ( Vsig 2 + Vsig 1 ) = Vcom$$

In combination with FIG. 1, the operation unit 800 is configured to determine a calibration signal based on a value of the second sensing signal and a value of the fifth sensing signal; the operation unit 800 is configured to determine the calibration signal based on a value of the first sensing signal.

In a specific example, the operation unit 800 is configured to determine the calibration signal based on a sum of the value of the second sensing signal and the value of the fifth sensing signal and the value of the first sensing signal.

For example, when the first direction X is defined as the positive direction, the value Vref of the calibration signal satisfies:

$$Vo 2 - 2 V 1 = ( Vsig 1 + Vsig 1 ) - 2 ( Vsig 1 - Vbr 1 ) = - 2 Vbr 1 = Vref$$

The magnetic field sensing device includes a second magnetic field generating unit 21.

The second magnetic field generating unit 21 is configured to apply a predetermined second excitation magnetic field Br2 to the second sensing unit 20. The direction and magnetic field intensity of the second excitation magnetic field Br2 are predetermined and known.

The second magnetic field generating unit 21 may be configured as structures such as a coil, magnet, or other structures capable of generating local magnetic fields to apply the second excitation magnetic field Br2.

The second magnetic field generating unit 21 may be arranged close to the second sensing unit 20 to apply the second excitation magnetic field Br2 to the second sensing unit 20.

Correspondingly, the ambient magnetic field sensed by the second sensing unit 20 includes the second excitation magnetic field Br2.

The second excitation magnetic field Br2 has a direction opposite to the first excitation magnetic field Br1. Specifically, the second excitation magnetic field Br2 has a direction opposite to and equal intensity as the first excitation magnetic field Br1.

The second magnetic field generating unit 21 may be configured as shown in the second example in FIG. 6.

The magnetic field sensing device comprises a fifth magnetic field generating unit 51.

The fifth magnetic field generating unit 51 is configured to apply a predetermined fifth excitation magnetic field Br5 to the fifth sensing unit 50. The direction and magnetic field intensity of the fifth excitation magnetic field Br5 are predetermined and known.

The fifth magnetic field generating unit 51 may be configured as structures such as a coil, magnet, or other structures capable of generating local magnetic fields to apply the fifth excitation magnetic field Br5.

The fifth magnetic field generating unit 51 may be arranged close to the fifth sensing unit 50 to apply the fifth excitation magnetic field Br5 to the fifth sensing unit 50.

Correspondingly, the ambient magnetic field sensed by the fifth sensing unit 50 includes the fifth excitation magnetic field Br5.

The fifth excitation magnetic field Br5 has a same direction as the second excitation magnetic field Br2. Specifically, the fifth excitation magnetic field Br5 has a same magnetic field intensity as the second excitation magnetic field Br2.

The fifth excitation magnetic field Br5 has a direction opposite to the first excitation magnetic field Br1. Specifically, the fifth excitation magnetic field Br5 has a same magnetic field intensity as the first excitation magnetic field Br1.

The fifth magnetic field generating unit 51 may be configured as shown in the eighth example in FIG. 12.

The magnetic field sensing device comprises a third magnetic field generating unit 31.

The third magnetic field generating unit 31 is configured to apply a predetermined third excitation magnetic field Br3 to the third sensing unit 30. The direction and magnetic field intensity of the third excitation magnetic field Br3 are predetermined and known.

The third magnetic field generating unit 31 may be configured as structures such as a coil, magnet, or other structures capable of generating local magnetic fields to apply the third excitation magnetic field Br3.

The third magnetic field generating unit 31 may be arranged close to the third sensing unit 30 to apply the third excitation magnetic field Br3 to the third sensing unit 30.

In a specific example, the third excitation magnetic field Br3 has a direction opposite to the first excitation magnetic field Br1. Specifically, the third excitation magnetic field Br3 has a direction opposite to and equal intensity as the first excitation magnetic field Br1.

In a specific example, the third excitation magnetic field Br3 has a same direction as the second excitation magnetic field Br2. Specifically, the third excitation magnetic field Br3 has a same direction and equal intensity as the second excitation magnetic field Br2.

The third magnetic field generating unit 31 may be configured as shown in the third example in FIG. 7.

The magnetic field sensing device comprises a sixth magnetic field generating unit 61.

The sixth magnetic field generating unit 61 is configured to apply a predetermined sixth excitation magnetic field Br6 to the sixth sensing unit 60. The direction and magnetic field intensity of the sixth excitation magnetic field Br6 are predetermined and known.

The sixth magnetic field generating unit 61 may be configured as structures such as a coil, magnet, or other structures capable of generating local magnetic fields to apply the sixth excitation magnetic field Br6.

The sixth magnetic field generating unit 61 may be arranged close to the sixth sensing unit 60 to apply the sixth excitation magnetic field Br6 to the sixth sensing unit 60.

Correspondingly, the ambient magnetic field sensed by the sixth sensing unit 60 includes the sixth excitation magnetic field Br6.

In a specific example, the sixth excitation magnetic field Br6 has a same direction as the third excitation magnetic field Br3. Specifically, the sixth excitation magnetic field Br6 has a same magnetic field intensity as the third excitation magnetic field Br3.

In a specific example, the sixth excitation magnetic field Br6 has a direction opposite to the first excitation magnetic field Br1. Specifically, the sixth excitation magnetic field Br6 has a same magnetic field intensity as the first excitation magnetic field Br1.

The sixth magnetic field generating unit 61 may be configured as shown in the eighth example in FIG. 12.

In combination with FIG. 1, the operation unit 800 is configured to determine the magnetic field sensing signal of the magnetic field sensing device based on a value of the second sensing signal and a value of the fifth sensing signal; the operation unit 800 is configured to determine the magnetic field sensing signal of the magnetic field sensing device based on a value of the third sensing signal and a value of the sixth sensing signal.

In a specific example, the operation unit 800 is configured to determine the magnetic field sensing signal of the magnetic field sensing device based on a sum of the value of the second sensing signal and the value of the fifth sensing signal and a sum of the value of the third sensing signal and the value of the sixth sensing signal.

The magnetic field sensing signal comprises a differential sensing signal corresponding to the first region S1 and the second region S2.

For example, when the first direction X is defined as the positive direction and Vbr3+Vbr6=Vbr2+Vbr5, the value Vdiff of the differential sensing signal satisfies:

$$Vo 3 - Vo 2 = ( ( Vsig 2 + Vbr 3 ) + ( Vsig 2 + Vbr 6 ) ) - ( ( Vsig 1 + Vbr 2 ) + ( Vsig 1 + Vbr 5 ) ) = 2 ( Vsig 2 - Vsig 1 ) = Vdiff$$

Preferably, Vbr3=Vbr6=Vbr2=Vbr5.

In combination with FIG. 1, the operation unit 800 is configured to determine a calibration signal based on a value of the second sensing signal and a value of the fifth sensing signal; the operation unit 800 is configured to determine the calibration signal based on a value of the first sensing signal.

In a specific example, the operation unit 800 is configured to determine the calibration signal based on a sum of the value of the second sensing signal and the value of the fifth sensing signal and the value of the first sensing signal.

For example, when the first direction X is defined as the positive direction and Vbr2=Vbr5=Vbr1, the value Vref of the calibration signal satisfies:

$$Vo 2 - 2 V 1 = ( ( Vsig 1 + Vbr 2 ) + ( Vsig 1 + Vbr 5 ) ) - 2 ( Vsig 1 - Vbr 1 ) = 4 Vbr 1 = Vref$$

In combination with FIG. 1, the operation unit 800 is configured to determine the magnetic field sensing signal of the magnetic field sensing device based on a value of the third sensing signal and a value of the sixth sensing signal; the operation unit 800 is configured to determine the magnetic field sensing signal of the magnetic field sensing device based on a value of the first sensing signal.

In a specific example, the operation unit 800 is configured to determine the magnetic field sensing signal of the magnetic field sensing device based on a sum of the value of the third sensing signal and the value of the sixth sensing signal and the value of the first sensing signal.

The magnetic field sensing signal includes a common-mode sensing signal corresponding to the first region S1 and the second region S2.

For example, when the first direction X is defined as the positive direction and Vbr3+Vbr6=2Vbr1, the value Vcom of the common-mode sensing signal satisfies:

$$\begin{matrix}Vo 3 + 2 V 1 = ( ( Vsig 2 + Vbr 3 ) + ( V sig 2 + Vbr 6 ) ) + 2 ( Vsig 1 - Vbr 1 ) \\ = 2 ( Vsig 2 + Vsig 1 ) = Vcom\end{matrix}$$

Preferably, Vbr3=Vbr6=Vbr1.

FIG. 21 shows a seventeenth example of the present application. The differences between the seventeenth example and the sixteenth example shown in FIG. 20 will be explained below, while similar aspects will not be repeated.

The second excitation magnetic field Br2 has a direction opposite to the first excitation magnetic field Br1. Specifically, the second excitation magnetic field Br2 has a direction opposite to and equal intensity as the first excitation magnetic field Br1.

The fifth excitation magnetic field Br5 has a same direction as the second excitation magnetic field Br2. Specifically, the fifth excitation magnetic field Br5 has a same magnetic field intensity as the second excitation magnetic field Br2. The fifth excitation magnetic field Br5 has a direction opposite to the first excitation magnetic field Br1. Specifically, the fifth excitation magnetic field Br5 has a same magnetic field intensity as the first excitation magnetic field Br1.

In a specific example, the third excitation magnetic field Br3 has a same direction as the first excitation magnetic field Br1. Specifically, the third excitation magnetic field Br3 has a same direction and equal intensity as the first excitation magnetic field Br1. The third excitation magnetic field Br3 has a direction opposite to the second excitation magnetic field Br2. Specifically, the third excitation magnetic field Br3 has a direction opposite to and equal intensity as the second excitation magnetic field Br2.

The sixth excitation magnetic field Br6 has a same direction as the third excitation magnetic field Br3. Specifically, the sixth excitation magnetic field Br6 has a same magnetic field intensity as the third excitation magnetic field Br3. In a specific example, the sixth excitation magnetic field Br6 has a same direction as the first excitation magnetic field Br1. Specifically, the sixth excitation magnetic field Br6 has a same magnetic field intensity as the first excitation magnetic field Br1.

In a specific example, the operation unit 800 is configured to determine the magnetic field sensing signal of the magnetic field sensing device based on a sum of the value of the second sensing signal and the value of the fifth sensing signal and a sum of the value of the third sensing signal and the value of the sixth sensing signal.

The magnetic field sensing signal includes a common-mode sensing signal corresponding to the first region S1 and the second region S2.

For example, when the first direction X is defined as the positive direction and Vbr3+Vbr6=Vbr2+Vbr5, the value Vcom of the common-mode sensing signal satisfies:

$$\begin{matrix}Vo 3 + Vo 2 = \begin{matrix}( ( Vsig 2 - Vbr 3 ) + ( V sig 2 - Vbr 6 ) ) + \\ ( ( Vsig 1 + Vbr 2 ) + ( Vsig 1 + Vbr 5 ) )\end{matrix} \\ 2 ( Vsig 2 + Vsig 1 ) = Vcom\end{matrix}$$

Preferably, Vbr3=Vbr6=Vbr2=Vbr5.

In a specific example, the operation unit 800 is configured to determine the magnetic field sensing signal of the magnetic field sensing device based on a sum of the value of the third sensing signal and the value of the sixth sensing signal and the value of the first sensing signal.

The magnetic field sensing signal includes a differential sensing signal corresponding to the first region S1 and the second region S2.

For example, when the first direction X is defined as the positive direction and Vbr3+Vbr6=2Vbr1, the value Vdiff of the differential sensing signal satisfies:

$$\begin{matrix}Vo 3 - 2 V 1 = ( ( Vsig 2 - Vbr 3 ) + ( V sig 2 - Vbr 6 ) ) - 2 ( Vsig 1 - Vbr 1 ) \\ = 2 ( Vsig 2 - Vsig 1 ) = Vdiff\end{matrix}$$

Preferably, Vbr3=Vbr6=Vbr1.

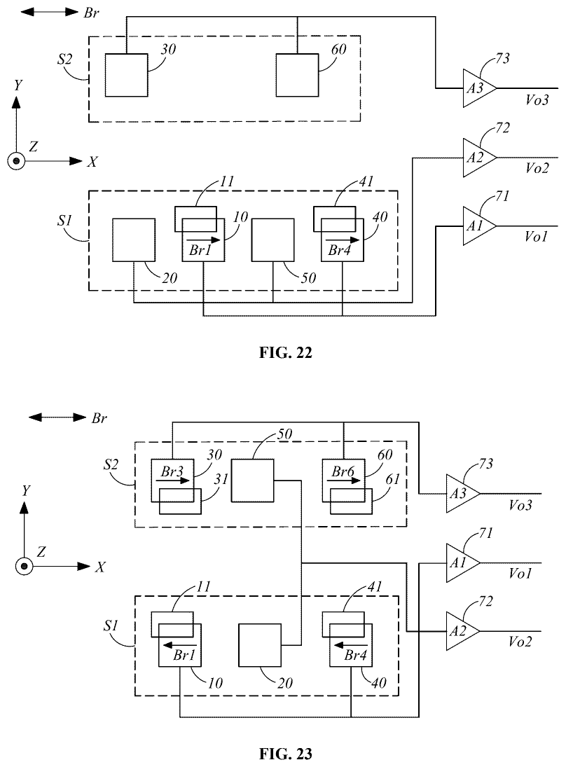

FIG. 22 shows an eighteenth example of the present application. The differences between the eighteenth example and the first example shown in FIG. 5 will be explained below, while similar aspects will not be repeated.

The magnetic field sensing device comprises a fourth sensing unit 40.

The fourth sensing unit 40 may be configured as shown in the fifth example in FIG. 9.

The fourth sensing unit 40 is arranged in the first region S1. The fourth sensing unit 40 may be located at a same position as the first sensing unit 10 or positioned close to the first sensing unit 10 within the first region S1.

The fourth sensing unit 40 is configured to sense an ambient magnetic field to generate a fourth sensing signal.

The ambient magnetic field sensed by the fourth sensing unit 40 includes either the overall ambient magnetic field of the environment where the magnetic field sensing device is located, or the magnetic field component of the ambient magnetic field at the first region S1.

In combination with FIG. 1, the operation unit 800 is configured to determine a calibration signal based on a value of the first sensing signal and a value of the fourth sensing signal; the operation unit 800 is configured to determine the calibration signal based on a value of the second sensing signal.

In a specific example, the operation unit 800 is configured to determine the calibration signal based on a sum of the value of the first sensing signal and the value of the fourth sensing signal and the value of the second sensing signal.

For example, when the first direction X is defined as the positive direction, the value Vref of the calibration signal satisfies:

$$Vo 1 - 2 V 2 = ( V 1 + V 4 ) - 2 V 2 = ( ( Vsig 1 - Vbr 1 ) + Vsig 1 ) - 2 Vsig 1 = - Vbr 1 = Vref$$

The magnetic field sensing device comprises a fourth magnetic field generating unit 41.

The fourth magnetic field generating unit 41 is configured to apply a predetermined fourth excitation magnetic field Br4 to the fourth sensing unit 40. The direction and magnetic field intensity of the fourth excitation magnetic field Br4 are predetermined and known.

The fourth magnetic field generating unit 41 may be configured as structures such as a coil, magnet, or other structures capable of generating local magnetic fields to apply the fourth excitation magnetic field Br4.

The fourth magnetic field generating unit 41 may be arranged close to the fourth sensing unit 40 to apply the fourth excitation magnetic field Br4 to the fourth sensing unit 40.

Correspondingly, the ambient magnetic field sensed by the fourth sensing unit 40 includes the fourth excitation magnetic field Br4.

In a specific example, the fourth excitation magnetic field Br4 has a same direction as the first excitation magnetic field Br1. Specifically, the fourth excitation magnetic field Br4 has a same direction and equal intensity as the first excitation magnetic field Br1.

The fourth magnetic field generating unit 41 may be configured as shown in the sixth example in FIG. 10 and the seventh example in FIG. 11.

In a specific example, the operation unit 800 is configured to determine the calibration signal based on a sum of the value of the first sensing signal and the value of the fourth sensing signal and the value of the second sensing signal.

For example, when the first direction X is defined as the positive direction and Vbr1=Vbr4, the value Vref of the calibration signal satisfies:

$$Vo 1 - 2 V 2 = ( V 1 + V 4 ) - 2 V 2 = ( ( Vsig 1 - Vbr 1 ) + ( Vsig 1 - ( Vbr4 ) ) - 2 Vsig 1 = - 2 Vbr 1 = Vref$$

The magnetic field sensing device comprises a fifth sensing unit 50.

The fifth sensing unit 50 is arranged in the first region S1.

The fifth sensing unit 50 is configured to sense an ambient magnetic field to generate a fifth sensing signal.

The ambient magnetic field sensed by the fifth sensing unit 50 includes either the overall ambient magnetic field of the environment where the magnetic field sensing device is located, or the magnetic field component of the ambient magnetic field at the first region S1.

The fifth sensing unit 50 may be configured as shown in the sixth example in FIG. 10.

The magnetic field sensing device comprises a sixth sensing unit 60.

The sixth sensing unit 60 is arranged in the second region S2.

The sixth sensing unit 60 is configured to sense an ambient magnetic field to generate a sixth sensing signal.

The ambient magnetic field sensed by the sixth sensing unit 60 includes either the overall ambient magnetic field of the environment where the magnetic field sensing device is located, or the magnetic field component of the ambient magnetic field at the second region S2.

The sixth sensing unit 60 may be configured as shown in the sixth example in FIG. 10.

In combination with FIG. 1, the operation unit 800 is configured to determine the magnetic field sensing signal of the magnetic field sensing device based on a value of the second sensing signal and a value of the fifth sensing signal; the operation unit 800 is configured to determine the magnetic field sensing signal of the magnetic field sensing device based on a value of the third sensing signal and a value of the sixth sensing signal.

In a specific example, the operation unit 800 is configured to determine the magnetic field sensing signal of the magnetic field sensing device based on a sum of the value of the second sensing signal and the value of the fifth sensing signal and a sum of the value of the third sensing signal and the value of the sixth sensing signal.

The magnetic field sensing signal includes a differential sensing signal and/or includes a common-mode sensing signal corresponding to the first region S1 and the second region S2.

For example, the value Vcom of the common-mode sensing signal satisfies:

$$Vo 2 + Vo 3 = V 2 + V 5 + V 3 + V 6 = 2 ( Vsig 1 + Vsig 2 ) = Vcom$$

The value Vdiff of the differential sensing signal satisfies:

$$Vo 3 - Vo 2 = ( V 3 + V 6 ) - ( V 2 + V 5 ) = 2 ( V sig 2 - Vsig 1 ) = Vdiff$$

The magnetic field sensing device further comprises a first amplifier 71. An input terminal of the first amplifier 71 is coupled to the first sensing unit 10 and the fourth sensing unit 40, and an output terminal of the first amplifier 71 is configured to generate a first intermediate output.

The magnetic field sensing device further comprises a second amplifier 72. An input terminal of the second amplifier 72 is coupled to the second sensing unit 20 and the fifth sensing unit 50, and an output terminal of the second amplifier 72 is configured to generate a second intermediate output.

The magnetic field sensing device further comprises a third amplifier 73. An input terminal of the third amplifier 73 is coupled to the third sensing unit 30 and the sixth sensing unit 60, and an output terminal of the third amplifier 73 is configured to generate a third intermediate output.

FIG. 23 shows a nineteenth example of the present application. The differences between the nineteenth example and the technical solution shown in FIG. 1 will be explained below, while similar aspects will not be repeated.

The magnetic field sensing device comprises a third sensing unit 30.

The third sensing unit 30 is arranged in the second region S2, which differs from the first region S1.

The third sensing unit 30 is configured to sense an ambient magnetic field to generate a third sensing signal.

The ambient magnetic field sensed by the third sensing unit 30 includes either the overall ambient magnetic field of the environment where the magnetic field sensing device is located, or the magnetic field component of the ambient magnetic field at the second region S2.

The third sensing unit 30 may be configured as shown in the first example in FIG. 5.

The magnetic field sensing device comprises a third magnetic field generating unit 31.

The third magnetic field generating unit 31 is configured to apply a predetermined third excitation magnetic field Br3 to the third sensing unit 30. The direction and magnetic field intensity of the third excitation magnetic field Br3 are predetermined and known.

The third magnetic field generating unit 31 may be configured as structures such as a coil, magnet, or other structures capable of generating local magnetic fields to apply the third excitation magnetic field Br3.

The third magnetic field generating unit 31 may be arranged close to the third sensing unit 30 to apply the third excitation magnetic field Br3 to the third sensing unit 30.

Correspondingly, the ambient magnetic field sensed by the third sensing unit 30 includes the third excitation magnetic field Br3.

In a specific example, the third excitation magnetic field Br3 has a direction opposite to the first excitation magnetic field Br1. Specifically, the third excitation magnetic field Br3 has a direction opposite to and equal intensity as the first excitation magnetic field Br1.

The third magnetic field generating unit 31 may be configured as shown in the third example in FIG. 7.

The magnetic field sensing device comprises a fifth sensing unit 50.

The fifth sensing unit 50 is arranged in the second region S2.

The fifth sensing unit 50 is configured to sense an ambient magnetic field to generate a fifth sensing signal.

The ambient magnetic field sensed by the fifth sensing unit 50 includes either the overall ambient magnetic field of the environment where the magnetic field sensing device is located, or the magnetic field component of the ambient magnetic field at the second region S2.

The fifth sensing unit 50 may be configured as shown in the sixth example in FIG. 10.

The magnetic field sensing device comprises a second amplifier 72. An input terminal of the second amplifier 72 is coupled to the second sensing unit 20 and the fifth sensing unit 50, and an output terminal of the second amplifier 72 is configured to generate a second intermediate output.

In combination with FIG. 1, the operation unit 800 is configured to determine a calibration signal based on a value of the first sensing signal; the operation unit 800 is configured to determine the calibration signal based on a value of the third sensing signal; the operation unit 800 is configured to determine the calibration signal based on a value of the fifth sensing signal and a value of the second sensing signal.

In a specific example, the operation unit 800 is configured to determine the calibration signal based on a value of the first sensing signal, the value of the third sensing signal, and a difference between the value of the fifth sensing signal and the value of the second sensing signal.

For example, when the first direction X is defined as the positive direction and Vbr3=Vbr1, the value Vref of the calibration signal satisfies:

$$V 3 - V 1 - Vo 2 = ( Vsig 2 + Vbr 3 ) - ( Vsig 1 - Vbr 1 ) - ( Vsig 2 - Vsig 1 ) = 2 Vbr 1 = Vref$$

In combination with FIG. 1, the operation unit 800 is configured to determine the magnetic field sensing signal of the magnetic field sensing device based on a value of the fifth sensing signal and a value of the second sensing signal.

In a specific example, the operation unit 800 is configured to determine the magnetic field sensing signal of the magnetic field sensing device based on a difference between the value of the fifth sensing signal and the value of the second sensing signal.

The magnetic field sensing signal includes a differential sensing signal corresponding to the first region S1 and the second region S2.

For example, when the first direction X is defined as the positive direction, the value Vdiff of the differential sensing signal satisfies:

$$Vo 2 = V 5 - V 2 = V sig 2 = Vsig 1 = Vdiff$$

In combination with FIG. 1, the operation unit 800 is configured to determine the magnetic field sensing signal of the magnetic field sensing device based on a value of the first sensing signal and a value of the third sensing signal.

In a specific example, the operation unit 800 is configured to determine the magnetic field sensing signal of the magnetic field sensing device based on a sum of the value of the first sensing signal and the value of the third sensing signal.

The magnetic field sensing signal includes a common-mode sensing signal corresponding to the first region S1 and the second region S2.

For example, when the first direction X is defined as the positive direction and Vbr1=Vbr3, the value Vcom of the common-mode sensing signal satisfies:

$$V 1 + V 3 = ( Vsig 1 - Vbr 1 ) + ( Vsig 2 + Vbr 3 ) = Vsig 1 + Vsig 2 = Vcom$$

In a specific example, the magnetic field sensing device comprises a fourth sensing unit 40.

The fourth sensing unit 40 may be configured as shown in the fifth example in FIG. 9.

The fourth sensing unit 40 is arranged in the first region S1. The fourth sensing unit 40 may be located at a same position as the first sensing unit 10 or positioned close to the first sensing unit 10 within the first region S1.

The fourth sensing unit 40 is configured to sense an ambient magnetic field to generate a fourth sensing signal.

The ambient magnetic field sensed by the fourth sensing unit 40 includes either the overall ambient magnetic field of the environment where the magnetic field sensing device is located, or the magnetic field component of the ambient magnetic field at the second region S2.

The magnetic field sensing device further comprises a first amplifier 71. An input terminal of the first amplifier 71 is coupled to the first sensing unit 10 and the fourth sensing unit 40, and an output terminal of the first amplifier 71 is configured to generate a first intermediate output.

In a specific example, the magnetic field sensing device comprises a sixth sensing unit 60.

The sixth sensing unit 60 is arranged in the second region S2.

The sixth sensing unit 60 is configured to sense an ambient magnetic field to generate a sixth sensing signal.

The ambient magnetic field sensed by the sixth sensing unit 60 includes either the overall ambient magnetic field of the environment where the magnetic field sensing device is located, or the magnetic field component of the ambient magnetic field at the second region S2.

The sixth sensing unit 60 may be configured as shown in the sixth example in FIG. 10.

The magnetic field sensing device further comprises a third amplifier 73. An input terminal of the third amplifier 73 is coupled to the third sensing unit 30 and the sixth sensing unit 60, and an output terminal of the third amplifier 73 is configured to generate a third intermediate output.

In combination with FIG. 1, the operation unit 800 is configured to determine the magnetic field sensing signal of the magnetic field sensing device based on a value of the first sensing signal and a value of the fourth sensing signal, and the value of the third sensing signal and the value of the sixth sensing signal.

In a specific example, the operation unit 800 is configured to determine the magnetic field sensing signal of the magnetic field sensing device based on a sum of the value of the first sensing signal and the value of the fourth sensing signal and a sum of the value of the third sensing signal and the value of the sixth sensing signal.

For example, when the first direction X is defined as the positive direction and Vbr1=Vbr3, the value Vcom of the common-mode sensing signal satisfies:

$$Vo 1 + Vo 3 = V 1 + V 4 + V 3 + V 6 = ( Vsig 1 - Vbr 1 ) + Vsig 1 ) + ( ( Vsig 2 + Vbr 3 ) + Vsig 2 ) = 2 ( Vsig 1 + Vsig 2 ) = Vcom$$

In combination with FIG. 1, the operation unit 800 is configured to determine a calibration signal based on a value of the first sensing signal and a value of the fourth sensing signal; the operation unit 800 is configured to determine the calibration signal based on a value of the third sensing signal and a value of the sixth sensing signal; the operation unit 800 is configured to determine the calibration signal based on a value of the fifth sensing signal and a value of the second sensing signal.

In a specific example, the operation unit 800 is configured to determine the calibration signal based on a sum of the value of the first sensing signal and the value of the fourth sensing signal, a sum of the value of the third sensing signal and the value of the sixth sensing signal, and a difference between the value of the fifth sensing signal and the value of the second sensing signal.

For example, when the first direction X is defined as the positive direction and Vbr3=Vbr1, the value Vref of the calibration signal satisfies:

$$\begin{matrix}Vo 3 - Vo 1 - 2 Vo 2 = ( V 3 + V 6 ) - ( V 1 + V 4 ) - 2 ( V 5 - V 2 ) \\ = \begin{matrix}( ( ( Vsig 2 + Vbr 3 ) + Vsig 2 ) - ( ( Vsig 1 - \\ Vbr 1 ) + Vsig 1 ) - 2 ( Vsig 2 - Vsig 1 )\end{matrix} \\ = 2 Vbr 1 = Vref\end{matrix}$$

In a specific example, the magnetic field sensing device comprises a fourth magnetic field generating unit 41.

The fourth magnetic field generating unit 41 is configured to apply a predetermined fourth excitation magnetic field Br4 to the fourth sensing unit 40. The direction and magnetic field intensity of the fourth excitation magnetic field Br4 are predetermined and known.

The fourth magnetic field generating unit 41 may be configured as structures such as a coil, magnet, or other structures capable of generating local magnetic fields to apply the fourth excitation magnetic field Br4.

The fourth magnetic field generating unit 41 may be arranged close to the fourth sensing unit 40 to apply the fourth excitation magnetic field Br4 to the fourth sensing unit 40.

Correspondingly, the ambient magnetic field sensed by the fourth sensing unit 40 includes the fourth excitation magnetic field Br4.

In a specific example, the fourth excitation magnetic field Br4 has a same direction as the first excitation magnetic field Br1. Specifically, the fourth excitation magnetic field Br4 has a same direction and equal intensity as the first excitation magnetic field Br1.

The fourth magnetic field generating unit 41 may be configured as shown in the sixth example in FIG. 10 and the seventh example in FIG. 11.

In a specific example, the magnetic field sensing device comprises a sixth magnetic field generating unit 61.

The sixth magnetic field generating unit 61 is configured to apply a predetermined sixth excitation magnetic field Br6 to the sixth sensing unit 60. The direction and magnetic field intensity of the sixth excitation magnetic field Br6 are predetermined and known.

The sixth magnetic field generating unit 61 may be configured as structures such as a coil, magnet, or other structures capable of generating local magnetic fields to apply the sixth excitation magnetic field Br6.

The sixth magnetic field generating unit 61 may be arranged close to the sixth sensing unit 60 to apply the sixth excitation magnetic field Br6 to the sixth sensing unit 60.

Correspondingly, the ambient magnetic field sensed by the sixth sensing unit 60 includes the sixth excitation magnetic field Br6.

In a specific example, the sixth excitation magnetic field Br6 has a same direction as the third excitation magnetic field Br3. Specifically, the sixth excitation magnetic field Br6 has a same magnetic field intensity as the third excitation magnetic field Br3.

In a specific example, the sixth excitation magnetic field Br6 has a direction opposite to the first excitation magnetic field Br1. Specifically, the sixth excitation magnetic field Br6 has a same magnetic field intensity as the first excitation magnetic field Br1.

The sixth magnetic field generating unit 61 may be configured as shown in the eighth example in FIG. 12.

In a specific example, the operation unit 800 is configured to determine the magnetic field sensing signal of the magnetic field sensing device based on a sum of the value of the first sensing signal and the value of the fourth sensing signal and a sum of the value of the third sensing signal and the value of the sixth sensing signal.

For example, when the first direction X is defined as the positive direction and Vbr1+Vbr4=Vbr3+Vbr6, the value Vcom of the common-mode sensing signal satisfies:

$$\begin{matrix}Vo 1 - Vo 3 = \begin{matrix}( ( Vsig 1 - Vbr 1 ) + ( Vsig 1 - Vbr 4 ) + \\ ( ( Vsig 2 += Vbr 3 ) + ( Vsig 2 + Vbr 6 ) )\end{matrix} \\ = 2 ( Vsig 1 + Vsig 2 ) = Vcom\end{matrix}$$

Preferably, Vbr1=Vbr4=Vbr3=Vbr6.

In a specific example, the operation unit 800 is configured to determine the calibration signal based on a sum of the value of the first sensing signal and the value of the fourth sensing signal, a sum of the value of the third sensing signal and the value of the sixth sensing signal, and a difference between the value of the fifth sensing signal and the value of the second sensing signal.

For example, when the first direction X is defined as the positive direction and Vbr3=Vbr1=Vbr6=Vbr4, the value Vref of the calibration signal satisfies:

$$Vo 3 - Vo 1 - 2 Vo 2 = ( ( Vsig 2 + Vbr 3 ) + ( Vsig 2 + Vbr 6 ) ) - ( ( Vsig 1 - Vbr 1 ) + ( Vsig 1 - Vbr 4 ) ) - 2 ( Vsig 2 - Vsig 1 )$$

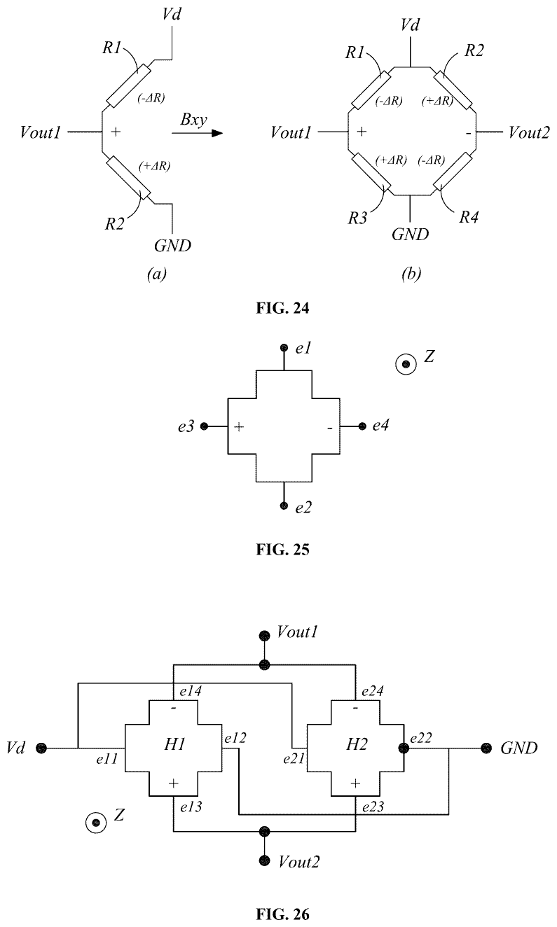

FIG. 24 shows a structure of a sensing unit in an embodiment of the present application. The structure can be applied to the first sensing unit 10 and/or the second sensing unit 20, as well as other sensing units described in the application.

For ease of description, the following will use sensing unit 100 as an example. The sensing unit 100 may be the first sensing unit 10, the second sensing unit 20, or other sensing units in the application.

As shown in FIG. 24(a), the sensing unit 100 comprises a first magnetoresistor R1.

The sensing unit 100 comprises a second magnetoresistor R2.

In an example, a first terminal of the first magnetoresistor R1 is coupled to a power supply terminal Vd; a first terminal of the second magnetoresistor R2 is coupled to a second terminal of the first magnetoresistor R1; a second terminal of the second magnetoresistor R2 is coupled to a ground terminal GND.

In an example, the sensing signal corresponding to the sensing unit 100 is related to a voltage value Vout1 at a second terminal of the first magnetoresistor R1.

In an example, the sensing signal is related to a voltage value Vout1 at a first terminal of the second magnetoresistor R2.

In an example, an output node is formed between a second terminal of the first magnetoresistor R1 and a first terminal of the second magnetoresistor R2 ; the output node is configure to output a sensing signal.

The configuration forms a half-bridge structure using magnetoresistors.

A magnetoresistor may exhibit a positive magnetoresistance effect (+ΔR) or a negative magnetoresistance effect (−ΔR). When a magnetoresistor exhibits a positive magnetoresistance effect (+ΔR), its resistance increases with the intensity of the applied magnetic field and decreases with the reduction of the magnetic field intensity. When a magnetoresistor exhibits a negative magnetoresistance effect (−ΔR), its resistance decreases with the intensity of the applied magnetic field and increases with the reduction of the magnetic field intensity.

In an example, the first magnetoresistor R1 exhibits a positive magnetoresistance effect (+ΔR), and the second magnetoresistor R2 exhibits a negative magnetoresistance effect (−ΔR).

In an example, the first magnetoresistor R1 exhibits a negative magnetoresistance effect (−ΔR), and the second magnetoresistor R2 exhibits a positive magnetoresistance effect (+ΔR).

As shown in FIG. 24(b), the sensing unit 100 comprises a first magnetoresistor R1.

The sensing unit 100 comprises a second magnetoresistor R2.

In an example, a first terminal of the first magnetoresistor R1 is coupled to a power supply terminal Vd; a first terminal of the second magnetoresistor R2 is coupled to a power supply terminal Vd.

In an example, a second terminal of the first magnetoresistor R1 is coupled to a ground terminal GND; a second terminal of the second magnetoresistor R2 is coupled to a ground terminal GND.

The second magnetoresistor R2 and the first magnetoresistor R1 have a predetermined magnetoresistance relationship.

In an example, the first magnetoresistor R1 exhibits a positive magnetoresistance effect (+ΔR), and the second magnetoresistor R2 exhibits a negative magnetoresistance effect (−ΔR).

In an example, the first magnetoresistor R1 exhibits a negative magnetoresistance effect (−ΔR), and the second magnetoresistor R2 exhibits a positive magnetoresistance effect (+ΔR).

In a preferred example, as shown in FIG. 24(b), a first terminal of the first magnetoresistor R1 is coupled to a power supply terminal Vd, and a first terminal of the second magnetoresistor R2 is coupled to a power supply terminal Vd. The first magnetoresistor R1 exhibits a negative magnetoresistance effect (−ΔR), and the second magnetoresistor R2 exhibits a positive magnetoresistance effect (+ΔR).

The sensing unit 100 further comprises a third magnetoresistor R3.

A first terminal of the third magnetoresistor R3 is coupled to a second terminal of the first magnetoresistor R1, and a second terminal of the third magnetoresistor R3 is coupled to a ground terminal GND.

A first terminal of the first magnetoresistor R1 is coupled to a power supply terminal Vd.

The configuration forms a half-bridge structure using magnetoresistors.

In an example, the sensing signal is related to a voltage value Vout1 at a second terminal of the first magnetoresistor R1.

In an example, the sensing signal is related to a voltage value Vout1 at a first terminal of the third magnetoresistor R3.

In an example, an output node is formed between a second terminal of the first magnetoresistor R1 and a first terminal of the third magnetoresistor R3 for generating the corresponding sensing signal.

The third magnetoresistor R3 and the first magnetoresistor R1 have a predetermined magnetoresistance relationship.

In an example, the first magnetoresistor R1 exhibits a negative magnetoresistance effect (−ΔR), and the third magnetoresistor R3 exhibits a positive magnetoresistance effect (+ΔR).

In an example, the first magnetoresistor R1 exhibits a positive magnetoresistance effect (+ΔR), and the third magnetoresistor R3 exhibits a negative magnetoresistance effect (−ΔR).

The sensing unit 100 further comprises a fourth magnetoresistor R4.

A first terminal of the fourth magnetoresistor R4 is coupled to a second terminal of the second magnetoresistor R2, and a second terminal of the fourth magnetoresistor R4 is coupled to a ground terminal GND.

A first terminal of the second magnetoresistor R2 is coupled to a power supply terminal Vd.

The configuration forms a half-bridge structure using magnetoresistors.

In an example, the sensing signal is related to a voltage value Vout2 at a second terminal of the second magnetoresistor R2.

In an example, the sensing signal is related to a voltage value Vout2 at a first terminal of the fourth magnetoresistor R4.

In an example, an output node is formed between a second terminal of the second magnetoresistor R2 and a first terminal of the fourth magnetoresistor R4 for generating the corresponding sensing signal.

The fourth magnetoresistor R4 and the second magnetoresistor R2 have a predetermined magnetoresistance relationship.

In an example, the second magnetoresistor R2 exhibits a negative magnetoresistance effect (−ΔR), and the fourth magnetoresistor R4 exhibits a positive magnetoresistance effect (+ΔR).

In an example, the second magnetoresistor R2 exhibits a positive magnetoresistance effect (+ΔR), and the fourth magnetoresistor R4 exhibits a negative magnetoresistance effect (−ΔR).

In a specific example, the first magnetoresistor R1 exhibits a negative magnetoresistance effect (−ΔR), the second magnetoresistor R2 exhibits a positive magnetoresistance effect (+ΔR), the third magnetoresistor R3 exhibits a positive magnetoresistance effect (+ΔR), and the fourth magnetoresistor R4 exhibits a negative magnetoresistance effect (−ΔR).

The four magnetoresistors form a full-bridge structure, with a voltage value Vout1 at a second terminal of the first magnetoresistor R1 and a voltage value Vout2 at a second terminal of the second magnetoresistor R2 serving as outputs. Specifically, the full-bridge structure uses the difference between Vout1 and Vout2 as the output to generate the corresponding sensing signal.

FIGS. 25 and 26 show structures of a sensing unit in another embodiment of the present application.

The sensing unit 100 comprises a first Hall element H1.

A detection direction of the first Hall element H1 is perpendicular to a plane where a Hall element is arranged (e.g., a plane where the first Hall element H1 is arranged). In an example, a detection direction of the first Hall element H1 is the third direction Z or its opposite direction. The detection direction of the first Hall element H1 indicates its sensitivity to magnetic field changes in that direction.

A first terminal e11 of the first Hall element H1 is coupled to a power supply terminal Vd; a second terminal e12 of the first Hall element H1 is coupled to a ground terminal GND.

The first Hall element H1 also includes a third terminal e13 and a fourth terminal e14. When the first Hall element H1 is energized and a magnetic field is applied along the Z-direction, charges deflect due to Lorentz force, creating a potential difference between the third terminal e13 and the fourth terminal e14.

The sensing unit 100 comprises a second Hall element H2.

A detection direction of the second Hall element H2 is perpendicular to a plane where a Hall element is arranged (e.g., a plane where the second Hall element H2 is arranged). In an example, a detection direction of the second Hall element H2 is the third direction Z. The detection direction of the second Hall element H2 indicates its sensitivity to magnetic field changes in that direction.

A first terminal e21 of the second Hall element H2 is coupled to a power supply terminal Vd; a second terminal e22 of the second Hall element H2 is coupled to a ground terminal GND.

The second Hall element H2 also includes a third terminal e23 and a fourth terminal e24. When the second Hall element H2 is energized and a magnetic field is applied along the Z-direction, charges deflect due to Lorentz force, creating a potential difference between the third terminal e23 and the fourth terminal e24.

A third terminal e23 of the second Hall element H2 is coupled to a third terminal e13 of the first Hall element H1, and a fourth terminal e24 of the second Hall element H2 is coupled to a fourth terminal e14 of the first Hall element H1. The configuration forms a dual-Hall structure using Hall elements.

A voltage value Vout1 at the coupled fourth terminals e14 of the first and second Hall elements H1 and H2, and a voltage value Vout2 at the coupled third terminals e13 of the first and second Hall elements H1 and H2 can serve as outputs.

After applying magnetic fields via a magnetic field generating unit (e.g., the first magnetic field generating unit 11 and/or the second magnetic field generator 21), the dual-Hall structure uses a difference between Vout1 and Vout2 as an output to generate the corresponding sensing signal.

In summary, the magnetic field sensing device provided by the present application employs two sensing units located in a same region, with one of them being subjected to a predetermined excitation magnetic field. By performing operations on signals generated by the two sensing units, a calibration signal representing the excitation magnetic field information is extracted. Since the information of the excitation magnetic field is predetermined, if the excitation magnetic field information contained in the calibration signal differs from the predetermined excitation magnetic field information, it can be determined that the magnetic field sensing device has an error, and the sensing signals can be calibrated based on the difference. In this process, as the two sensing units are located in a same region, it facilitates the formation of a calibration signal related to linear errors between the two sensing signals, thereby enabling targeted and rapid calibration. Since both sensing units are configured to be sensitive to the ambient magnetic field, the overall device exhibits high sensitivity.

It should be understood that although the specification describes embodiments or examples individually, each embodiment or example may not contain an independent technical solution. The description format is for clarity, and those skilled in the art should treat the specification as a whole. Technical solutions from different embodiments or examples may be combined to form other implementations understandable to those skilled in the art.

The detailed descriptions above are specific explanations of feasible embodiments or examples of the present application and are not intended to limit its scope. Any equivalent implementations or modifications made without departing from the spirit of the present application shall fall within the protection scope of the present application.

What is claimed is:

1. A magnetic field sensing device, wherein comprising:
a first magnetic field generating unit, configured to apply a predetermined first excitation magnetic field to a first sensing unit;
a first sensing unit, arranged in a first region, configured to sense an ambient magnetic field to generate a first sensing signal;
a second sensing unit, arranged in the first region, configured to sense an ambient magnetic field to generate a second sensing signal;
an operation unit, configured to generate a calibration signal based on the first sensing signal and the second sensing signal, wherein the calibration signal includes information corresponding to the first excitation magnetic field, and the calibration signal is configured to calibrate the first sensing signal and/or the second sensing signal.

2. The magnetic field sensing device according to claim 1, wherein the operation unit satisfies at least one of the following:
the operation unit is configured to calibrate the first sensing signal and/or the second sensing signal based on a difference between a value of the calibration signal and a first predetermined value, wherein the first predetermined value is determined according to a magnetic field intensity of the first excitation magnetic field;
an output terminal of the operation unit is coupled to an input terminal of the first sensing unit and/or an input terminal of the second sensing unit, configured to adjust a driving current of the first sensing unit and/or the second sensing unit;
an output terminal of the operation unit is coupled to an input terminal of the first sensing unit and/or an input terminal of the second sensing unit, configured to adjust a driving voltage of the first sensing unit and/or the second sensing unit;
an output terminal of the operation unit is coupled to a first amplifier and/or a second amplifier, configured to adjust an amplification factor of the first amplifier and/or the second amplifier; an input terminal of the first amplifier is coupled to an output terminal of the first sensing unit, an output terminal of the first amplifier is coupled to a first input terminal of the operation unit; an input terminal of the second amplifier is coupled to an output terminal of the second sensing unit, an output terminal of the second amplifier is coupled to a second input terminal of the operation unit;
the operation unit is configured to adjust a computational gain of the first sensing signal and/or the second sensing signal based on the calibration signal.

3. The magnetic field sensing device according to claim 1, wherein further comprising:
a third sensing unit, arranged in a second region different from the first region, configured to sense an ambient magnetic field to generate a third sensing signal;
the operation unit determines a magnetic field sensing signal of the magnetic field sensing device based on a value of the second sensing signal and a value of the third sensing signal.

4. The magnetic field sensing device according to claim 1, wherein further comprising:
a second magnetic field generating unit, configured to apply a predetermined second excitation magnetic field to the second sensing unit, wherein the second excitation magnetic field has a direction opposite to the first excitation magnetic field;
wherein the ambient magnetic field sensed by the first sensing unit comprises the first excitation magnetic field and a first signal magnetic field corresponding to the first region;
wherein the ambient magnetic field sensed by the second sensing unit comprises the second excitation magnetic field and the first signal magnetic field;
wherein the operation unit satisfies at least one of the following:
determining the first signal magnetic field based on a sum of a value of the first sensing signal and a value of the second sensing signal;
determining the calibration signal based on a difference between the value of the first sensing signal and the value of the second sensing signal.

5. The magnetic field sensing device according to claim 1, wherein further comprising:
a third magnetic field generating unit, configured to apply a predetermined third excitation magnetic field to a third sensing unit, wherein the third excitation magnetic field has a direction same as the first excitation magnetic field;
a third sensing unit, arranged in a second region different from the first region, configured to sense an ambient magnetic field to generate a third sensing signal;
wherein the ambient magnetic field sensed by the first sensing unit comprises the first excitation magnetic field and a first signal magnetic field corresponding to the first region;
wherein the ambient magnetic field sensed by the third sensing unit comprises the third excitation magnetic field and a second signal magnetic field corresponding to the second region;
wherein the operation unit determines a magnetic field sensing signal of the magnetic field sensing device based on a difference between a value of the third sensing signal and a value of the first sensing signal.

6. The magnetic field sensing device according to claim 3, wherein further comprising:
a fourth sensing unit, arranged in the second region, configured to sense an ambient magnetic field to generate a fourth sensing signal;
wherein the operation unit determines the calibration signal based on a value of the first sensing signal and a value of the fourth sensing signal, and a value of the second sensing signal and a value of the third sensing signal.

7. The magnetic field sensing device according to claim 6, wherein further comprising:
a fifth sensing unit, arranged in the first region, configured to sense an ambient magnetic field to generate a fifth sensing signal;
a sixth sensing unit, arranged in the second region, configured to sense an ambient magnetic field to generate a sixth sensing signal;
wherein the operation unit determines a magnetic field sensing signal of the magnetic field sensing device based on a sum of a value of the second sensing signal and a value of the fifth sensing signal, and a sum of a value of the third sensing signal and a value of the sixth sensing signal.

8. The magnetic field sensing device according to claim 7, wherein further comprising:
a second magnetic field generating unit, configured to apply a predetermined second excitation magnetic field to the second sensing unit;
a third magnetic field generating unit, configured to apply a predetermined third excitation magnetic field to the third sensing unit, wherein the third excitation magnetic field has a direction opposite to the second excitation magnetic field;
a fourth magnetic field generating unit, configured to apply a predetermined fourth excitation magnetic field to the fourth sensing unit, wherein the fourth excitation magnetic field has a direction opposite to the first excitation magnetic field;
a fifth magnetic field generating unit, configured to apply a predetermined fifth excitation magnetic field to the fifth sensing unit, wherein the fifth excitation magnetic field has a direction same as the second excitation magnetic field;
a sixth magnetic field generating unit, configured to apply a predetermined sixth excitation magnetic field to the sixth sensing unit, wherein the sixth excitation magnetic field has a direction same as the third excitation magnetic field;
wherein the operation unit satisfies at least one of the following:
determining a magnetic field sensing signal of the magnetic field sensing device based on a sum of a value of the second sensing signal and a value of the fifth sensing signal, a sum of a value of the third sensing signal and a value of the sixth sensing signal, and a difference between a value of the first sensing signal and a value of the fourth sensing signal;
determining the calibration signal based on a sum of the value of the second sensing signal and the value of the fifth sensing signal, a sum of the value of the third sensing signal and the value of the sixth sensing signal, and a difference between the value of the first sensing signal and the value of the fourth sensing signal.

9. The magnetic field sensing device according to claim 7, wherein further comprising:
a second magnetic field generating unit, configured to apply a predetermined second excitation magnetic field to the second sensing unit;
a third magnetic field generating unit, configured to apply a predetermined third excitation magnetic field to the third sensing unit, wherein the third excitation magnetic field has a direction opposite to the second excitation magnetic field;
a fourth magnetic field generating unit, configured to apply a predetermined fourth excitation magnetic field to the fourth sensing unit, wherein the fourth excitation magnetic field has a direction same as the first excitation magnetic field;
a fifth magnetic field generating unit, configured to apply a predetermined fifth excitation magnetic field to the fifth sensing unit, wherein the fifth excitation magnetic field has a direction same as the second excitation magnetic field;
a sixth magnetic field generating unit, configured to apply a predetermined sixth excitation magnetic field to the sixth sensing unit, wherein the sixth excitation magnetic field has a direction same as the third excitation magnetic field;
wherein the operation unit satisfies at least one of the following:
determining a magnetic field sensing signal of the magnetic field sensing device based on a sum of a value of the second sensing signal and a value of the fifth sensing signal, and a sum of a value of the first sensing signal and a value of the fourth sensing signal;
determining the calibration signal based on a sum of the value of the second sensing signal and the value of the fifth sensing signal, a sum of a value of the third sensing signal and a value of the sixth sensing signal, and a sum of the value of the first sensing signal and the value of the fourth sensing signal.

10. The magnetic field sensing device according to claim 7, wherein further comprising:
a second magnetic field generating unit, configured to apply a predetermined second excitation magnetic field to the second sensing unit;
a third magnetic field generating unit, configured to apply a predetermined third excitation magnetic field to the third sensing unit, wherein the third excitation magnetic field has a direction same as the second excitation magnetic field;
a fourth magnetic field generating unit, configured to apply a predetermined fourth excitation magnetic field to the fourth sensing unit;
a fifth magnetic field generating unit, configured to apply a predetermined fifth excitation magnetic field to the fifth sensing unit, wherein the fifth excitation magnetic field has a direction same as the second excitation magnetic field;
a sixth magnetic field generating unit, configured to apply a predetermined sixth excitation magnetic field to the sixth sensing unit, wherein the sixth excitation magnetic field has a direction same as the third excitation magnetic field;
wherein the operation unit satisfies at least one of the following:
when the second excitation magnetic field has a direction same as the first excitation magnetic field and the fourth excitation magnetic field has a direction opposite to the first excitation magnetic field, determining a magnetic field sensing signal of the magnetic field sensing device based on a sum of a value of the second sensing signal and a value of the fifth sensing signal, and a difference between a value of the first sensing signal and a value of the fourth sensing signal;
when the second excitation magnetic field has a direction same as the first excitation magnetic field and the fourth excitation magnetic field has a direction opposite to the first excitation magnetic field, determining the calibration signal based on a sum of the value of the second sensing signal and the value of the fifth sensing signal, a sum of a value of the third sensing signal and a value of the sixth sensing signal, and a difference between the value of the first sensing signal and the value of the fourth sensing signal;
when the second excitation magnetic field has a direction opposite to the first excitation magnetic field and the fourth excitation magnetic field has a direction same as the first excitation magnetic field, determining a magnetic field sensing signal of the magnetic field sensing device based on a sum of the value of the second sensing signal and the value of the fifth sensing signal, a sum of the value of the third sensing signal and the value of the sixth sensing signal, and a sum of the value of the first sensing signal and the value of the fourth sensing signal;
when the second excitation magnetic field has a direction opposite to the first excitation magnetic field and the fourth excitation magnetic field has a direction same as the first excitation magnetic field, determining the calibration signal based on a sum of the value of the second sensing signal and the value of the fifth sensing signal, a sum of the value of the third sensing signal and the value of the sixth sensing signal, and a sum of the value of the first sensing signal and the value of the fourth sensing signal.

11. The magnetic field sensing device according to claim 7, wherein further comprising:
a third magnetic field generating unit, configured to apply a predetermined third excitation magnetic field to the third sensing unit, wherein the third excitation magnetic field has a direction opposite to the first excitation magnetic field;
a sixth magnetic field generating unit, configured to apply a predetermined sixth excitation magnetic field to the sixth sensing unit, wherein the sixth excitation magnetic field has a direction same as the third excitation magnetic field;
wherein the operation unit determines a magnetic field sensing signal of the magnetic field sensing device based on a sum of a value of the second sensing signal and a value of the fifth sensing signal, a sum of a value of the third sensing signal and a value of the sixth sensing signal, and a difference between a value of the first sensing signal and a value of the fourth sensing signal.

12. The magnetic field sensing device according to claim 6, wherein further comprising:
a second magnetic field generating unit, configured to apply a predetermined second excitation magnetic field to the second sensing unit;
a third magnetic field generating unit, configured to apply a predetermined third excitation magnetic field to the third sensing unit, wherein the third excitation magnetic field has a direction opposite to the second excitation magnetic field;
a fifth sensing unit, arranged in the first region, configured to sense an ambient magnetic field to generate a fifth sensing signal;
a fifth magnetic field generating unit, configured to apply a predetermined fifth excitation magnetic field to the fifth sensing unit, wherein the fifth excitation magnetic field has a direction same as the second excitation magnetic field;
a sixth sensing unit, arranged in the second region, configured to sense an ambient magnetic field to generate a sixth sensing signal;
a sixth magnetic field generating unit, configured to apply a predetermined sixth excitation magnetic field to the sixth sensing unit, wherein the sixth excitation magnetic field has a direction same as the third excitation magnetic field;
wherein the operation unit satisfies at least one of the following:
determining a magnetic field sensing signal of the magnetic field sensing device based on a difference between a value of the third sensing signal and a value of the second sensing signal, a difference between a value of the sixth sensing signal and a value of the fifth sensing signal, and a difference between a value of the first sensing signal and a value of the fourth sensing signal;
determining the calibration signal based on a difference between the value of the third sensing signal and the value of the second sensing signal, a difference between the value of the sixth sensing signal and the value of the fifth sensing signal, and a difference between the value of the first sensing signal and the value of the fourth sensing signal.

13. The magnetic field sensing device according to claim 3, wherein further comprising:
a fifth sensing unit, arranged in the first region, configured to sense an ambient magnetic field to generate a fifth sensing signal;
a sixth sensing unit, arranged in the second region, configured to sense an ambient magnetic field to generate a sixth sensing signal;
a second magnetic field generating unit, configured to apply a predetermined second excitation magnetic field to the second sensing unit;
a third magnetic field generating unit, configured to apply a predetermined third excitation magnetic field to the third sensing unit;
a fifth magnetic field generating unit, configured to apply a predetermined fifth excitation magnetic field to the fifth sensing unit, wherein the fifth excitation magnetic field has a direction same as the second excitation magnetic field;
a sixth magnetic field generating unit, configured to apply a predetermined sixth excitation magnetic field to the sixth sensing unit, wherein the sixth excitation magnetic field has a direction same as the third excitation magnetic field;
wherein the operation unit satisfies at least one of the following:
determining the calibration signal based on a sum of a value of the second sensing signal and a value of the fifth sensing signal, and a value of the first sensing signal;
determining a magnetic field sensing signal of the magnetic field sensing device based on a sum of a value of the third sensing signal and a value of the sixth sensing signal, and a value of the first sensing signal;
determining a magnetic field sensing signal of the magnetic field sensing device based on a sum of a value of the second sensing signal and a value of the fifth sensing signal, and a sum of a value of the third sensing signal and a value of the sixth sensing signal.

14. The magnetic field sensing device according to claim 3, wherein further comprising:
a fourth sensing unit, arranged in the first region, configured to sense an ambient magnetic field to generate a fourth sensing signal;
a fourth magnetic field generating unit, configured to apply a predetermined fourth excitation magnetic field to the fourth sensing unit, wherein the fourth excitation magnetic field has a direction same as the first excitation magnetic field;
wherein the operation unit determines the calibration signal based on a sum of a value of the first sensing signal and a value of the fourth sensing signal, and the second sensing signal.

15. The magnetic field sensing device according to claim 1, wherein further comprising:
a third sensing unit, arranged in a second region different from the first region, configured to sense an ambient magnetic field to generate a third sensing signal;
a third magnetic field generating unit, configured to apply a predetermined third excitation magnetic field to the third sensing unit, wherein the third excitation magnetic field has a direction opposite to the first excitation magnetic field;
a fifth sensing unit, arranged in the second region, configured to sense an ambient magnetic field to generate a fifth sensing signal;
wherein the operation unit satisfies at least one of the following:
determining the calibration signal based on a value of the first sensing signal, a value of the third sensing signal, and a difference between a value of the fifth sensing signal and a value of the second sensing signal;
determining a magnetic field sensing signal of the magnetic field sensing device based on a difference between the value of the fifth sensing signal and the value of the second sensing signal;
determining a magnetic field sensing signal of the magnetic field sensing device based on a sum of a value of the first sensing signal and a value of the third sensing signal.
